(19) United States
(12) Patent Application Publication
(10) Pub. No.: US 2013/0037790 A1
(43) Pub. Date: Feb. 14, 2013

(54) NOVEL 10,10-DIALKYLANTHRONE COMPOUND AND ORGANIC LIGHT-EMITTING DEVICE INCLUDING THE SAME

(71) Applicants: Jun Kamatani, Tokyo (JP); Yosuke Nishide, Kawasaki-shi (JP); Naoki Yamada, Inagi-shi (JP); Akihito Saitoh, Gotemba-shi (JP)

(72) Inventors: Jun Kamatani, Tokyo (JP); Yosuke Nishide, Kawasaki-shi (JP); Naoki Yamada, Inagi-shi (JP); Akihito Saitoh, Gotemba-shi (JP)

(73) Assignee: CANON KABUSHIKI KAISHA, Tokyo (JP)

(21) Appl. No.: 13/643,059

(22) PCT Filed: Apr. 11, 2011
(86) PCT No.: PCT/JP2011/059468

§ 371 Date: Oct. 23, 2012

(30) Foreign Application Priority Data
Apr. 26, 2010 (JP) 2010-101298

(51) Int. Cl. H01L 51/54

(52) U.S. Cl. 257/40; 257/E51.026

(57) ABSTRACT

A novel stable 10,10-dialkylanthrone compound is provided.

### TECHNICAL FIELD

The present invention relates to a novel 10,10-dialkylanthrone compound and an organic light-emitting device including the 10,10-dialkylanthrone compound.

### BACKGROUND ART

An organic light-emitting device is a device that includes an anode, a cathode, and an organic compound layer interposed between the anode and the cathode. Holes and electrons injected from the respective electrodes of the organic light-emitting device are recombined in the organic compound layer to generate excitons and light is emitted as the excitons return to their ground state. Recent years have seen remarkable advances in the field of organic light-emitting devices. Organic light-emitting devices offer low driving voltage, various emission wavelengths, rapid response, and small thickness and are light-weight.

Phosphorescence-emitting devices are a type of organic light-emitting device that includes an organic compound layer containing a phosphorescent material, with triplet excitons contributing to emission. Improvements on the emission efficiency of phosphorescent organic light-emitting devices are desired.

PTL 1 discloses an organic light-emitting device in which a compound H-1 (anthrone) below is described as an intermediate that occurs during synthesis of anthracene.

PTL 2 discloses a compound H-2 below used as a material contained in a hole transport layer of a fluorescence-emitting organic light-emitting device.

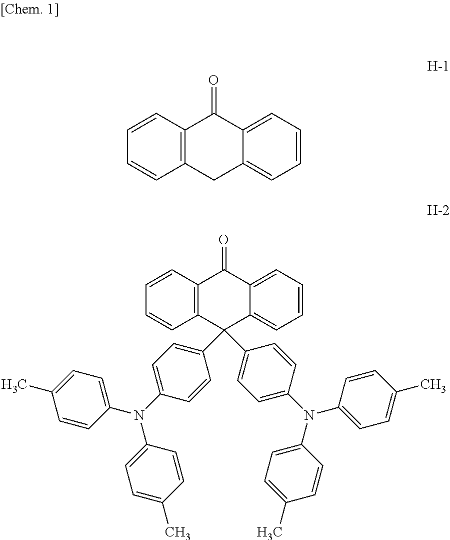

The compounds described in PTL 1 and 2 have the 10-position of the anthrone skeleton substituted with hydrogen or an aryl group and are thus unstable. Moreover, PTL 1 and 2 fail to focus on and utilize the electron transport property of the anthrone skeleton.

Development of organic compounds that form an electron transport layer of an organic light-emitting device having an emission layer is also desired. In particular, a chemically stable organic compound that has a deep lowest unoccupied molecular orbital (LUMO) level of 2.7 eV or more is desired.

An organic compound having a high T₁ energy is particularly desirable for use as an organic compound contained in an organic light-emitting device that includes an emission layer containing a phosphorescent material.

### CITATION LIST

### Patent Literature

PTL 1 Japanese Patent Laid-Open No. 2002-338957
PTL 2 Japanese Patent Laid-Open No. 08-259937

### SUMMARY OF INVENTION

The present invention provides a 10,10-dialkylanthrone compound represented by general formula [1] below.

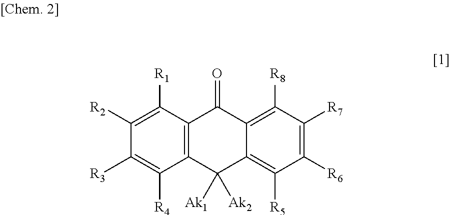

In formula [1], R₁ to R₈ are each independently selected from a hydrogen atom, an alkyl group having 1 to 4 carbon atoms, a phenyl group, a biphenyl group, a naphthyl group, a phenanthrene group, a fluorenyl group, a triphenylene group, a dibenzofuran group, and a dibenzothiophene group; and Ak₁ and Ak₂ are each individually selected from alkyl groups having 1 to 6 carbon atoms.

### BRIEF DESCRIPTION OF DRAWINGS

FIG. 1 is a schematic cross-sectional view of an organic light-emitting device and a switching element connected to the organic light-emitting device.

### DESCRIPTION OF EMBODIMENTS

A 10,10-dialkylanthrone compound according to an embodiment of the invention is represented by general formula [1]:

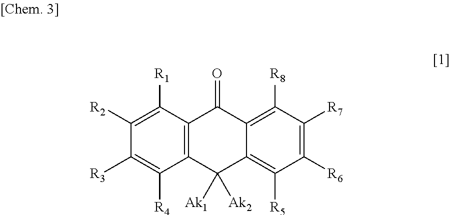

In general formula [1], R₁ to R₈ are each independently selected from a hydrogen atom, an alkyl group having 1 to 4 carbon atoms, a phenyl group, a biphenyl group, a naphthyl group, a phenanthrene group, a fluorenyl group, a triphenylene group, a dibenzofuran group, and a dibenzothiophene group.

Examples of the alkyl group having 1 to 4 carbon atoms include a methyl group, an ethyl group, an n-propyl group, an iso-propyl group, an n-butyl group, an iso-butyl group, a sec-butyl group, and a tert-butyl group.

The phenyl group, the biphenyl group, the naphthyl group, the phenanthrene group, the fluorenyl group, the triphenylene group, the dibenzofuran group, and the dibenzothiophene group may have a substituent. Examples of the substituents include alkyl groups such as a methyl group, an ethyl group, an n-propyl group, an iso-propyl group, an n-butyl group, an iso-butyl group, a sec-butyl group, and a tert-butyl group; aromatic hydrocarbon groups such as a phenyl group, a naphthyl group, a phenanthryl group, and a fluorenyl group; heteroaromatic groups such as a thienyl group, a dibenzofuran group, a dibenzothiophene group, a pyrrolyl group, and a pyridyl group; alkoxy groups such as a methoxy group and an ethoxy group; aryloxy groups such as a phenoxy group and a naphthoxy group; and halogen atoms such as fluorine, chlorine, bromine, and iodine.

Examples of the alkyl groups having 1 to 6 carbon atoms represented by Ak₁ and Ak₂ include a methyl group, an ethyl group, an n-propyl group, an iso-propyl group, an n-butyl group, an iso-butyl group, a sec-butyl group, a tert-butyl group, an n-pentyl group, and an n-hexyl group.

The 10,10-dialkylanthrone compound can provide a stable, novel 10,10-dialkylanthrone compound having a T₁ energy as high as 3.1 eV and a LUMO level as deep as 2.7 eV or more by itself. An organic light-emitting device containing this compound thus offers high emission efficiency and stability.

### Regarding the Properties of the 10,10-Dialkylanthrone Compound

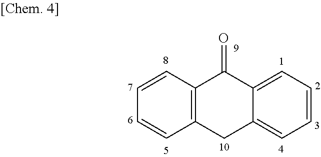 [SMILES: O=C1c2ccccc2Cc2ccccc21]

The 10-position of the anthrone skeleton has high reactivity and thus the anthrone skeleton is often used as an intermediate in the following reaction scheme of synthesizing anthracene.

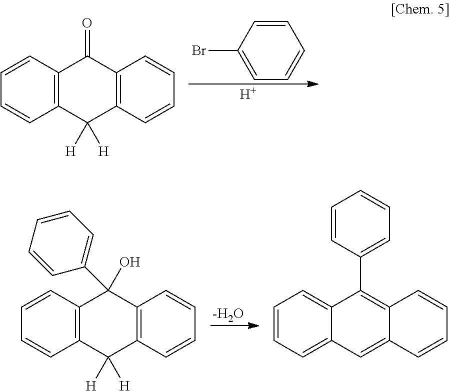

This reaction is caused by hydrogen atoms at the 10-position of anthrone. Substituting the hydrogen atoms at the 10-position of anthrone with alkyl groups will stabilize the molecule.

When the carbon atom at the 10-position of the anthrone skeleton is quaternary carbon having no hydrogen and the four substituents bonded to this carbon atom are alkyl and aryl groups, the reactivity of the carbon atom increases with the number of aryl groups.

This is because of the following reason. When one of the substituents of the carbon atom is removed, a carbocation occurs on the carbon atom at the 10-position of the anthrone skeleton. When the carbocation occurs, the carbon atom becomes more and more unstable as the number of aryl groups serving as substituents increases. Accordingly, when an organic compound having a quaternary carbon atom having many aryl groups is used in an organic light-emitting device, a carbocation is likely to occur and the stability of the device tends to be low because of the intermolecular reaction. In particular, a molecule having a quaternary carbon atom having four aryl groups as substituents is unstable. A molecule is more stable when all of the substituents for the 10-position of the anthrone skeleton are alkyl groups.

In view of the above, when an anthrone skeleton is used in an organic light-emitting device, substituting the 10-position of anthrone with alkyl groups will provide a stable organic light-emitting device.

As shown in formula [1], the anthrone skeleton has a carbonyl group at the 9-position in the skeleton. The inventors have noticed that the anthrone skeleton is suitable as an electron transport material because of the electron transport property derived from the carbonyl group.

When a hole transport substituent, such as an arylamino group, is selected as the substituent that directly bonds to the 10-position of the anthrone skeleton represented by formula [1], the amino group and the carbonyl group interact with each other, thereby narrowing the T₁ energy to about 2.0 V. Note that an electron transport material refers to a material having an electron transport property higher than a hole transport property. This means that if an amino group is introduced as a substituent into the anthrone skeleton, the compound cannot be used as an electron transport material since the hole transport property of the amino group is higher than the electron transport property of the carbonyl group.

Accordingly, the substituents bonding to the positions other than the 10-position of the anthrone skeleton represented by formula [1] may be substituents that also have an electron transport property, e.g., an alkyl group, an aryl group, dibenzofuran, or dibenzothiophene.

In sum, the 10,10-dialkylanthrone compound described here is a chemically stable organic compound that has an electron mobility higher than the hole mobility and is highly suitable as an electron transport material.

When the compound is used in an electron transport layer or an emission layer of an organic light-emitting device, i.e., when the anthrone compound is used as a compound other than the light-emitting material of the organic light-emitting device, the following points should be taken into account. That is, it is important that the anthrone compound have a band gap optimum for the emission color of the light-emitting material contained in that organic light-emitting device.

In order to narrow the band gap of the anthrone compound, a substituent, such as an aryl group, that has a conjugation is introduced to a position at which the anthrone skeleton and the conjugation are connected. The substitution position which is the position at which the conjugation is connected is the 1-position to the 8-position of the anthrone skeleton. Thus, an aryl group may be introduced into the 1- to 8-positions of the anthrone skeleton. Since the 10-position is occupied by the SP3 carbon, introduction of an aryl group to the 10-position does not cause a continuous conjugation. Thus, the wavelength cannot be controlled and the compound has a band gap derived from the anthrone skeleton.

In order to control the band gap to be narrower by expanding the conjugation, a substituent may be provided at a substitution position of low steric hindrance with the anthrone skeleton. The positions where the substituents are provided are more preferably R₂, R₃, R₆, and R₇ and most preferably one of R₂ and R₃ and one of R₆ and R₇. Yet more preferably, when a substituent is provided in R₂, the other substituent is provided in R₇, and when a substituent is provided in R₃, the other substituent is provided in R₆. In this case, all of R₁, R₄, R₅, and R₈ are preferably a hydrogen atom. The substituents may be the same as the other.

When the light-emitting material of an organic light-emitting device is a phosphorescent material and when the organic light-emitting device contains the anthrone compound in at least one of the emission layer and a transport layer adjacent to the emission layer, the T₁ energy of the anthrone compound is important.

When the emission color of the phosphorescent material is blue to red, i.e., the maximum peak of the spectrum of the emission wavelength is in the range of 440 nm to 620 nm, it is important that the T₁ energy of the anthrone compound be determined according to the emission color of the phosphorescent material.

In determining the T₁ energy of the anthrone compound, the T₁ energy of the substituent (fused ring) bonded to one of R₁ to R₈ in general formula [1] is brought to focus.

Table 1 below shows the T₁ energy (on a wavelength basis) of benzene and typical fused rings. Of these, preferred structures are benzene, naphthalene, phenanthrene, fluorene, triphenylene, chrysene, dibenzofuran, dibenzothiophene, and pyrene.

When the emission color of the phosphorescent material is blue to green, the structure bonded to one of R₁ to R₈ is preferably benzene, naphthalene, phenanthrene, fluorene, triphenylene, dibenzofuran, or dibenzothiophene. Note that “blue to green” means the range of 440 nm to 530 nm.

The anthrone compound of the embodiment can be used in at least one of an electron transport layer and an emission layer of a phosphorescent organic light-emitting device. This is because the T₁ energy of the anthrone compound is higher than that of the phosphorescent material. The anthrone compound has a band gap sufficient to be suitable for use in such layers.

TABLE 1

| | | T₁ energy on |
|---|---|---|
| | Structural | wavelength |
| | formula | basis |
| Benzene | 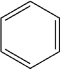 | 339 nm |
| Naphthalene | 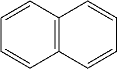 | 472 nm |
| Phenanthrene | 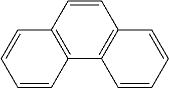 [SMILES: c1ccc2c(c1)ccc1ccccc12] | 459 nm |
| Fluorene | 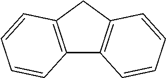 [SMILES: c1ccc2c(c1)Cc1ccccc1-2] | 422 nm |
| Triphenylene | 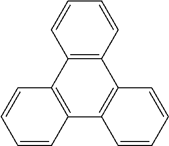 [SMILES: c1ccc2c(c1)c1ccccc1c1ccccc21] | 427 nm |
| Chrysene | 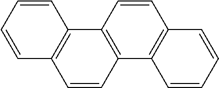 [SMILES: c1ccc2c(c1)ccc1c3ccccc3ccc21] | 500 nm |
| Dibenzofuran | 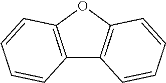 [SMILES: c1ccc2c(c1)oc1ccccc12] | 417 nm |
| Dibenzothiophene | 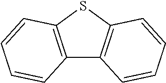 [SMILES: c1ccc2c(c1)sc1ccccc12] | 415 nm |
| Anthracene | 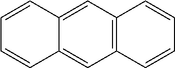 [SMILES: c1ccc2cc3ccccc3cc2c1] | 672 nm |
| Pyrene | 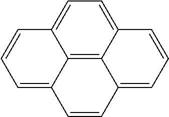 [SMILES: c1cc2ccc3cccc4ccc(c1)c2c34] | 589 nm |

Regarding the Properties of an Organic Light-Emitting Device that Uses the 10,10-Dialkylanthrone Compound

The compound of the embodiment is mainly used in an emission layer, or at least one of a hole blocking layer, an electron transport layer, and an electron injection layer of an organic light-emitting device.

The emission layer may be composed of two or more components which can be categorized as main and auxiliary components. A main component is a compound that has the largest weight ratio among all compounds constituting the emission layer and may be referred to as a “host material”.

An auxiliary component is any compound other than the main component. The auxiliary component may be referred to as a guest (dopant) material, an emission assisting material, or a charge injection material. An emission assisting material and a charge injection material may be organic compounds having the same or different structures. An auxiliary component may be referred to as a “host material 2” to distinguish from the guest material.

A guest material is a compound contributing to the main emission in the emission layer. In contrast, a host material is a compound that functions as a matrix surrounding the guest material in the emission layer and has functions of transporting carriers and supplying excitation energy to the guest material.

The guest material concentration is 0.01 to 50 wt % and preferably 0.1 to 20 wt % relative to the total amount of the materials constituting the emission layer. More preferably, the guest material concentration is 10 wt % or less to prevent concentration quenching. The guest material may be homogeneously distributed in the entire layer composed of a host material, may be contained in the layer by having a concentration gradient, or may be contained in particular parts of the layer, thereby creating parts containing the host material only.

The compound of the embodiment is mainly used as a host material or an electron injection material of an emission layer containing a phosphorescent material as a guest material, or an electron transport material of an electron transport layer. The emission color of the phosphorescent material is not particularly limited, but may be blue to green with a maximum emission peak wavelength in the range of 440 nm to 530 nm.

In general, in order to prevent a decrease in emission efficiency caused by radiationless deactivation from T₁ of the host material of a phosphorescent organic light-emitting device, the T₁ energy of the host material needs to be higher than the T₁ energy of the phosphorescent material which is a guest material.

The T₁ energy of the anthrone skeleton which is at the center of the compound of the embodiment is 397 nm and is thus higher than the T₁ energy of a blue phosphorescent material. When the compound is used in the emission layer or nearby layers of an organic light-emitting device having blue to green emission, an organic light-emitting device having high emission efficiency can be obtained.

Since the compound of the embodiment has a deep LUMO level, the driving voltage of the device can be decreased by using the compound as an electron injection material, an electron transport material, a material of a hole blocking layer, or a host material 2 of the emission layer. This is because a deep LUMO level lowers the barrier to electron injection from the electron transport layer or the hole blocking layer adjacent to the cathode side of the emission layer.

### Examples of the 10,10-Dialkylanthrone Compound

Specific examples of structural formulae of the 10,10-dialkylanthrone compound of the embodiment are as follows.

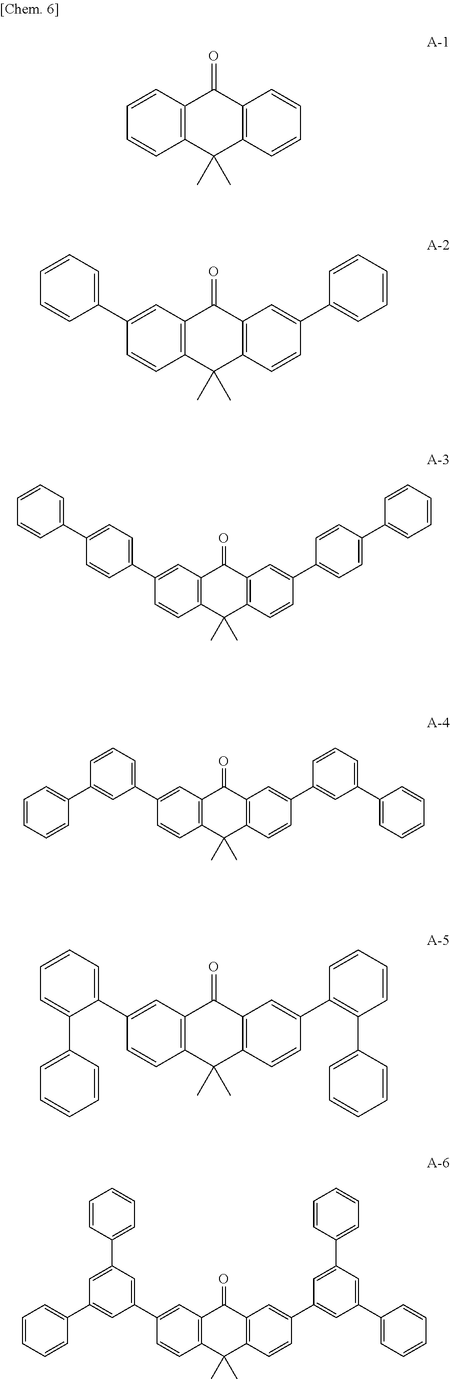 [SMILES: CC1(C)c2ccccc2C(=O)c2ccccc21 ; CC1(C)c2ccc(-c3ccccc3)cc2C(=O)c2cc(-c3ccccc3)ccc21 ; CC1(C)c2ccc(-c3ccc(-c4ccccc4)cc3)cc2C(=O)c2cc(-c3ccc(-c4ccccc4)cc3)ccc21 ; CC1(C)c2ccc(-c3cccc(-c4ccccc4)c3)cc2C(=O)c2cc(-c3cccc(-c4ccccc4)c3)ccc21 ; CC1(C)c2ccc(-c3ccccc3-c3ccccc3)cc2C(=O)c2cc(-c3ccccc3-c3ccccc3)ccc21 ; CC1(C)c2ccc(-c3cc(-c4ccccc4)cc(-c4ccccc4)c3)cc2C(=O)c2cc(-c3cc(-c4ccccc4)cc(-c4ccccc4)c3)ccc21]

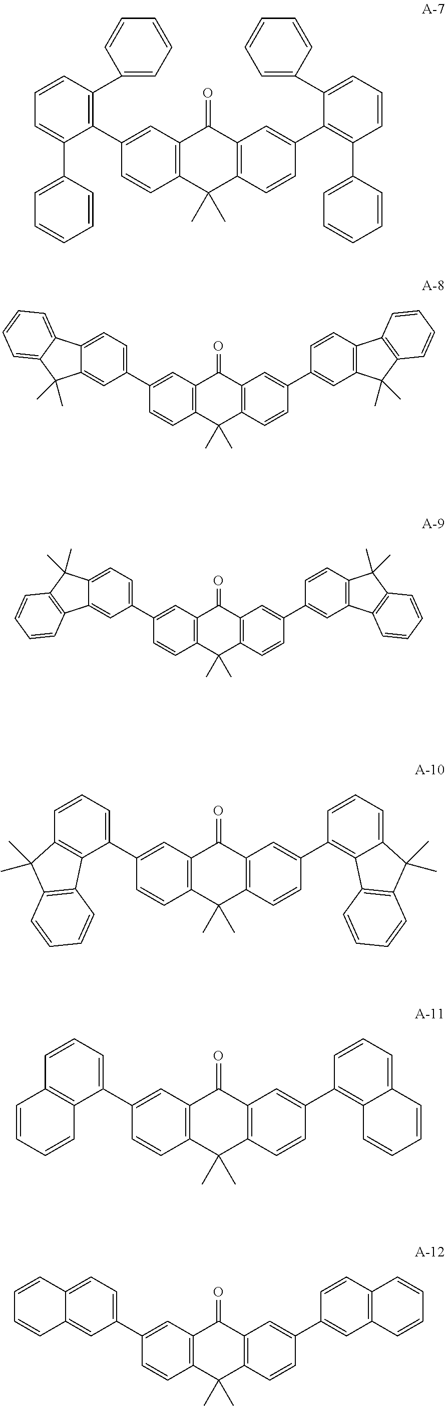

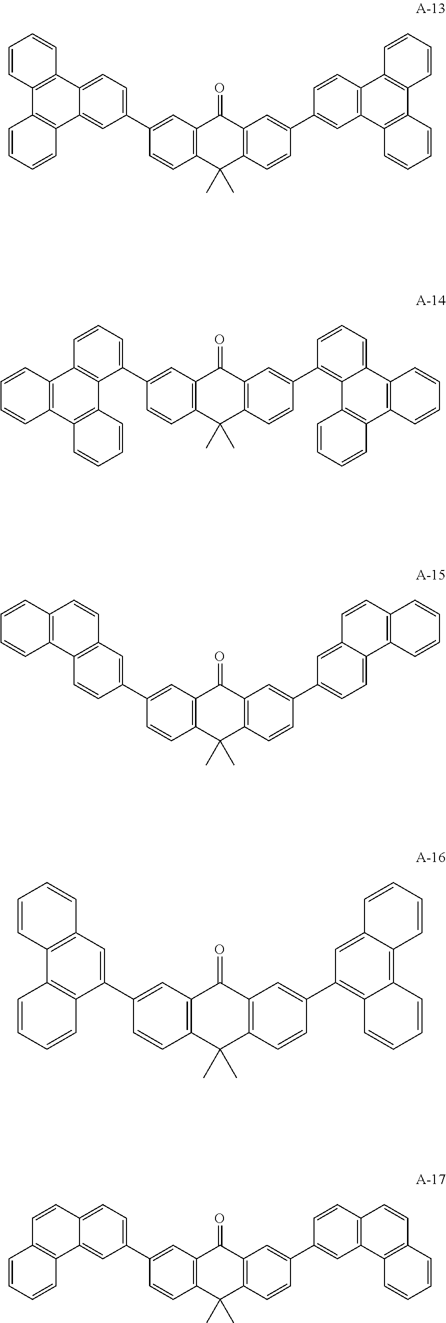 [SMILES: CC1(C)c2ccc(-c3ccc4c5ccccc5c5ccccc5c4c3)cc2C(=O)c2cc(-c3ccc4c5ccccc5c5ccccc5c4c3)ccc21 ; CC1(C)c2ccc(-c3cccc4c5ccccc5c5ccccc5c34)cc2C(=O)c2cc(-c3cccc4c5ccccc5c5ccccc5c34)ccc21 ; CC1(C)c2ccc(-c3ccc4c(ccc5ccccc54)c3)cc2C(=O)c2cc(-c3ccc4c(ccc5ccccc54)c3)ccc21 ; CC1(C)c2ccc(-c3cc4ccccc4c4ccccc34)cc2C(=O)c2cc(-c3cc4ccccc4c4ccccc34)ccc21 ; CC1(C)c2ccc(-c3ccc4ccc5ccccc5c4c3)cc2C(=O)c2cc(-c3ccc4ccc5ccccc5c4c3)ccc21]

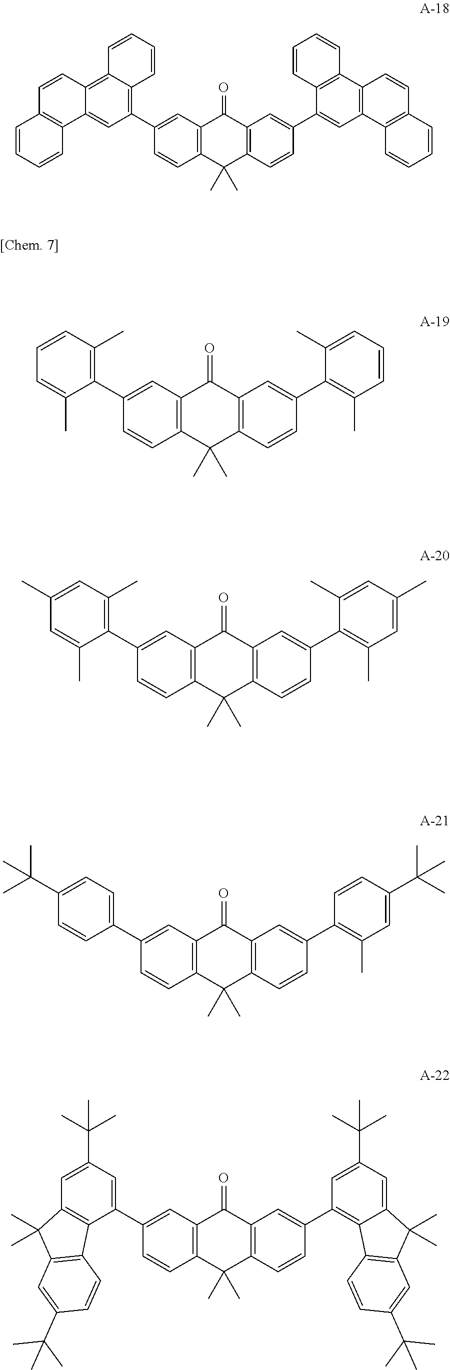

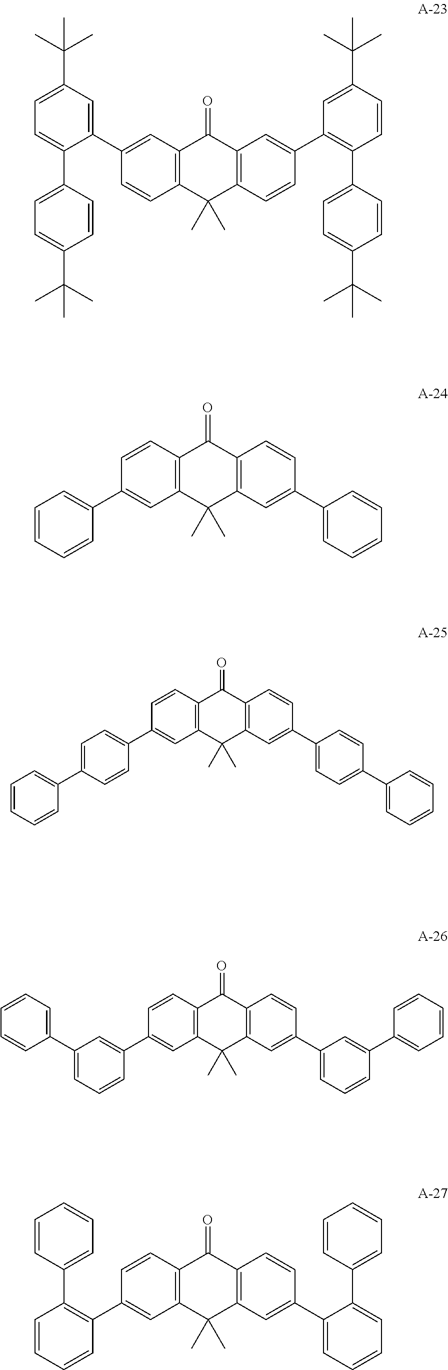 [SMILES: CC(C)(C)c1ccc(-c2ccc(C(C)(C)C)cc2-c2ccc3c(c2)C(=O)c2cc(-c4cc(C(C)(C)C)ccc4-c4ccc(C(C)(C)C)cc4)ccc2C3(C)C)cc1 ; CC1(C)c2cc(-c3ccccc3)ccc2C(=O)c2ccc(-c3ccccc3)cc21 ; CC1(C)c2cc(-c3ccc(-c4ccccc4)cc3)ccc2C(=O)c2ccc(-c3ccc(-c4ccccc4)cc3)cc21 ; CC1(C)c2cc(-c3cccc(-c4ccccc4)c3)ccc2C(=O)c2ccc(-c3cccc(-c4ccccc4)c3)cc21 ; CC1(C)c2cc(-c3ccccc3-c3ccccc3)ccc2C(=O)c2ccc(-c3ccccc3-c3ccccc3)cc21]

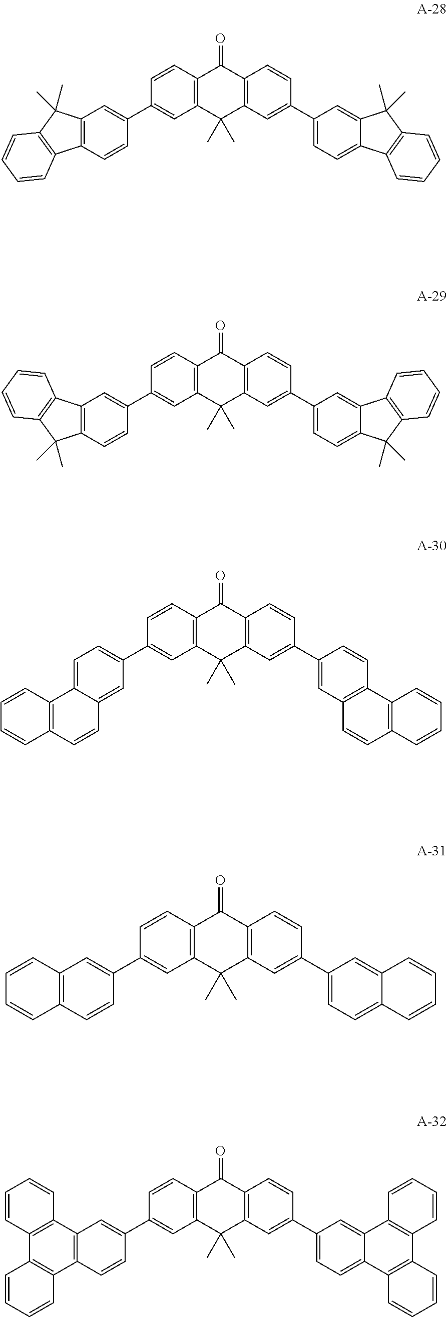 [SMILES: CC1(C)c2cc(-c3ccc4c(c3)C(C)(C)c3ccccc3-4)ccc2C(=O)c2ccc(-c3ccc4c(c3)C(C)(C)c3ccccc3-4)cc21 ; CC1(C)c2cc(-c3ccc4c(c3)-c3ccccc3C4(C)C)ccc2C(=O)c2ccc(-c3ccc4c(c3)-c3ccccc3C4(C)C)cc21 ; CC1(C)c2cc(-c3ccc4c(ccc5ccccc54)c3)ccc2C(=O)c2ccc(-c3ccc4c(ccc5ccccc54)c3)cc21 ; CC1(C)c2cc(-c3ccc4ccccc4c3)ccc2C(=O)c2ccc(-c3ccc4ccccc4c3)cc21 ; CC1(C)c2cc(-c3ccc4c5ccccc5c5ccccc5c4c3)ccc2C(=O)c2ccc(-c3ccc4c5ccccc5c5ccccc5c4c3)cc21]

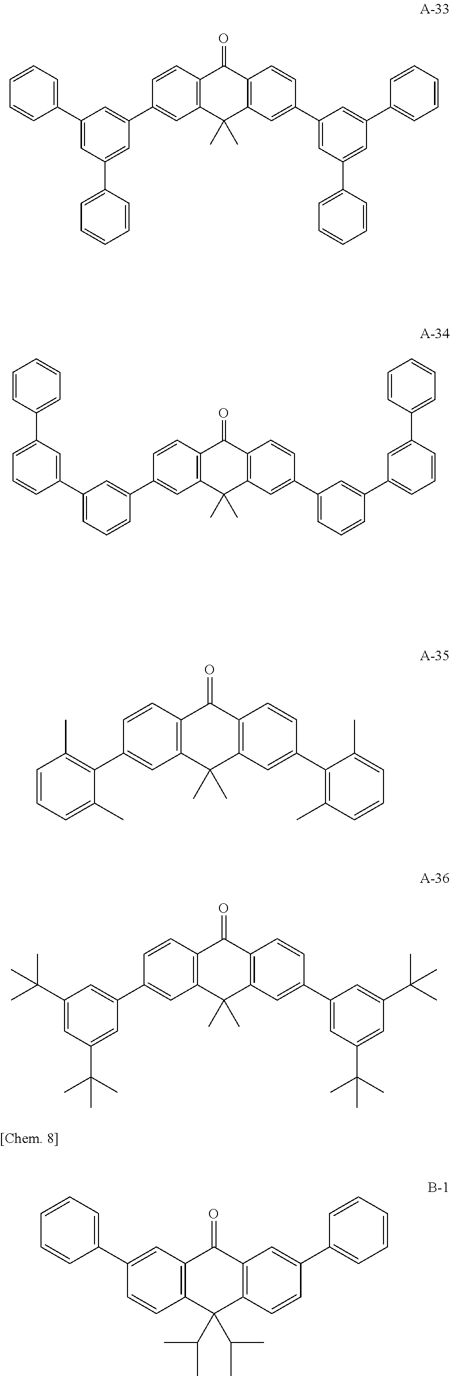 [SMILES: CC1(C)c2cc(-c3cc(-c4ccccc4)cc(-c4ccccc4)c3)ccc2C(=O)c2ccc(-c3cc(-c4ccccc4)cc(-c4ccccc4)c3)cc21 ; CC1(C)c2cc(-c3cccc(-c4cccc(-c5ccccc5)c4)c3)ccc2C(=O)c2ccc(-c3cccc(-c4cccc(-c5ccccc5)c4)c3)cc21 ; Cc1cccc(C)c1-c1ccc2c(c1)C(C)(C)c1cc(-c3c(C)cccc3C)ccc1C2=O ; CC(C)(C)c1cc(-c2ccc3c(c2)C(C)(C)c2cc(-c4cc(C(C)(C)C)cc(C(C)(C)C)c4)ccc2C3=O)cc(C(C)(C)C)c1 ; CC(C)C1(C(C)C)c2ccc(-c3ccccc3)cc2C(=O)c2cc(-c3ccccc3)ccc21]

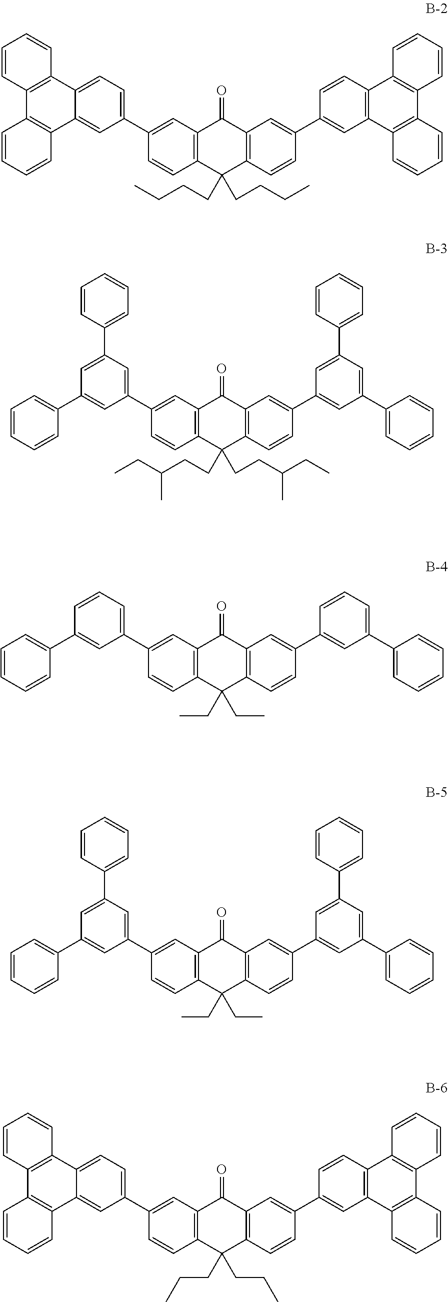 [SMILES: CCCCC1(CCCC)c2ccc(-c3ccc4c5ccccc5c5ccccc5c4c3)cc2C(=O)c2cc(-c3ccc4c5ccccc5c5ccccc5c4c3)ccc21 ; CCC(C)CCC1(CCC(C)CC)c2ccc(-c3cc(-c4ccccc4)cc(-c4ccccc4)c3)cc2C(=O)c2cc(-c3cc(-c4ccccc4)cc(-c4ccccc4)c3)ccc21 ; CCC1(CC)c2ccc(-c3cccc(-c4ccccc4)c3)cc2C(=O)c2cc(-c3cccc(-c4ccccc4)c3)ccc21 ; CCC1(CC)c2ccc(-c3cc(-c4ccccc4)cc(-c4ccccc4)c3)cc2C(=O)c2cc(-c3cc(-c4ccccc4)cc(-c4ccccc4)c3)ccc21 ; CCCC1(CCC)c2ccc(-c3ccc4c5ccccc5c5ccccc5c4c3)cc2C(=O)c2cc(-c3ccc4c5ccccc5c5ccccc5c4c3)ccc21]

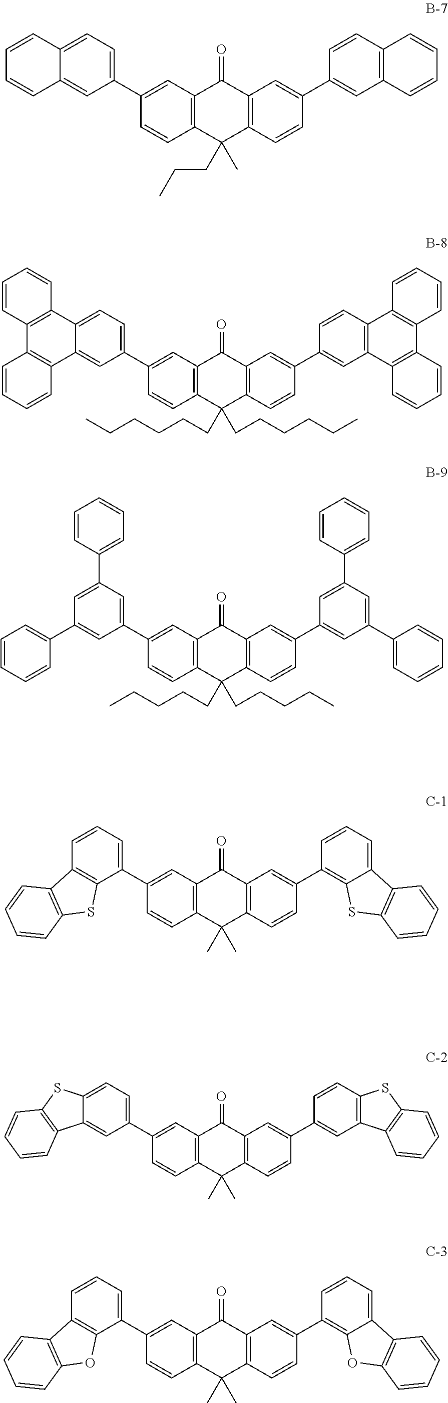 [SMILES: CCCC1(C)c2ccc(-c3ccc4ccccc4c3)cc2C(=O)c2cc(-c3ccc4ccccc4c3)ccc21 ; CCCCCCC1(CCCCCC)c2ccc(-c3ccc4c5ccccc5c5ccccc5c4c3)cc2C(=O)c2cc(-c3ccc4c5ccccc5c5ccccc5c4c3)ccc21 ; CCCCCC1(CCCCC)c2ccc(-c3cc(-c4ccccc4)cc(-c4ccccc4)c3)cc2C(=O)c2cc(-c3cc(-c4ccccc4)cc(-c4ccccc4)c3)ccc21 ; CC1(C)c2ccc(-c3cccc4c3sc3ccccc34)cc2C(=O)c2cc(-c3cccc4c3sc3ccccc34)ccc21 ; CC1(C)c2ccc(-c3ccc4sc5ccccc5c4c3)cc2C(=O)c2cc(-c3ccc4sc5ccccc5c4c3)ccc21 ; CC1(C)c2ccc(-c3cccc4c3oc3ccccc34)cc2C(=O)c2cc(-c3cccc4c3oc3ccccc34)ccc21]

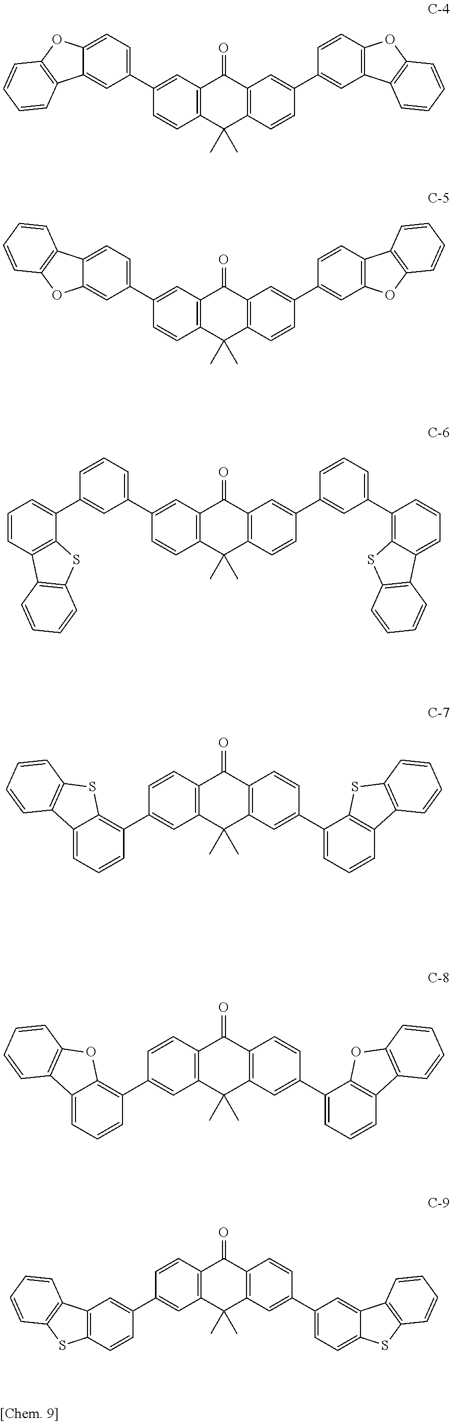 [SMILES: CC1(C)c2ccc(-c3ccc4oc5ccccc5c4c3)cc2C(=O)c2cc(-c3ccc4oc5ccccc5c4c3)ccc21 ; CC1(C)c2ccc(-c3ccc4c(c3)oc3ccccc34)cc2C(=O)c2cc(-c3ccc4c(c3)oc3ccccc34)ccc21 ; CC1(C)c2ccc(-c3cccc(-c4cccc5c4sc4ccccc45)c3)cc2C(=O)c2cc(-c3cccc(-c4cccc5c4sc4ccccc45)c3)ccc21 ; CC1(C)c2cc(-c3cccc4c3sc3ccccc34)ccc2C(=O)c2ccc(-c3cccc4c3sc3ccccc34)cc21 ; CC1(C)c2cc(-c3cccc4c3oc3ccccc34)ccc2C(=O)c2ccc(-c3cccc4c3oc3ccccc34)cc21 ; CC1(C)c2cc(-c3ccc4sc5ccccc5c4c3)ccc2C(=O)c2ccc(-c3ccc4sc5ccccc5c4c3)cc21]

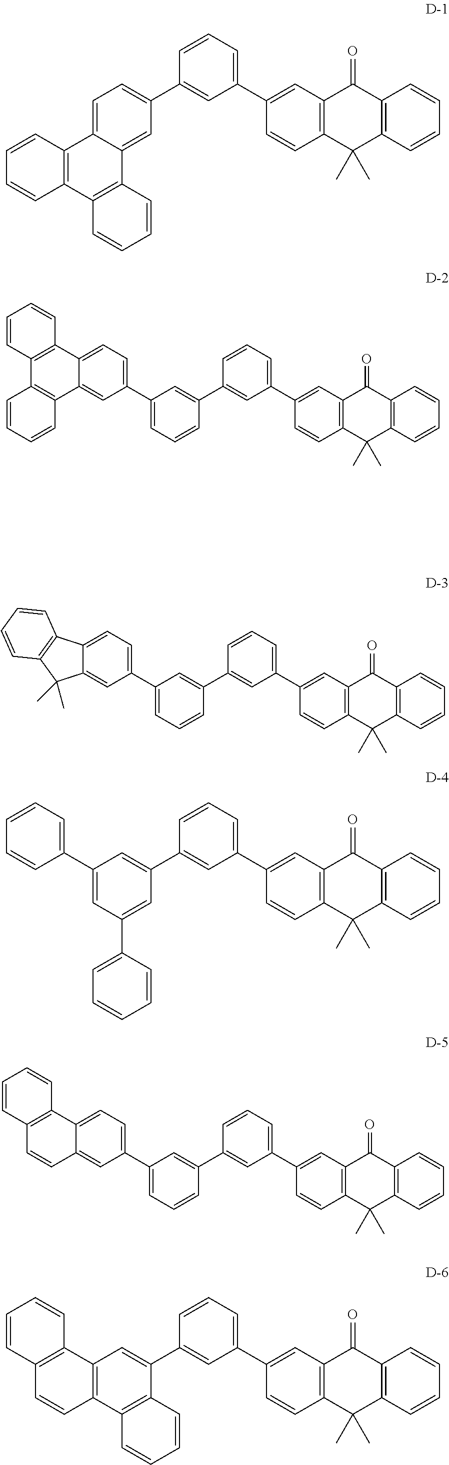 [SMILES: CC1(C)c2ccccc2C(=O)c2cc(-c3cccc(-c4ccc5c6ccccc6c6ccccc6c5c4)c3)ccc21 ; CC1(C)c2ccccc2C(=O)c2cc(-c3cccc(-c4cccc(-c5ccc6c7ccccc7c7ccccc7c6c5)c4)c3)ccc21 ; CC1(C)c2ccccc2C(=O)c2cc(-c3cccc(-c4cccc(-c5ccc6c(c5)C(C)(C)c5ccccc5-6)c4)c3)ccc21 ; CC1(C)c2ccccc2C(=O)c2cc(-c3cccc(-c4cc(-c5ccccc5)cc(-c5ccccc5)c4)c3)ccc21 ; CC1(C)c2ccccc2C(=O)c2cc(-c3cccc(-c4cccc(-c5ccc6c(ccc7ccccc76)c5)c4)c3)ccc21 ; CC1(C)c2ccccc2C(=O)c2cc(-c3cccc(-c4cc5c6ccccc6ccc5c5ccccc45)c3)ccc21]

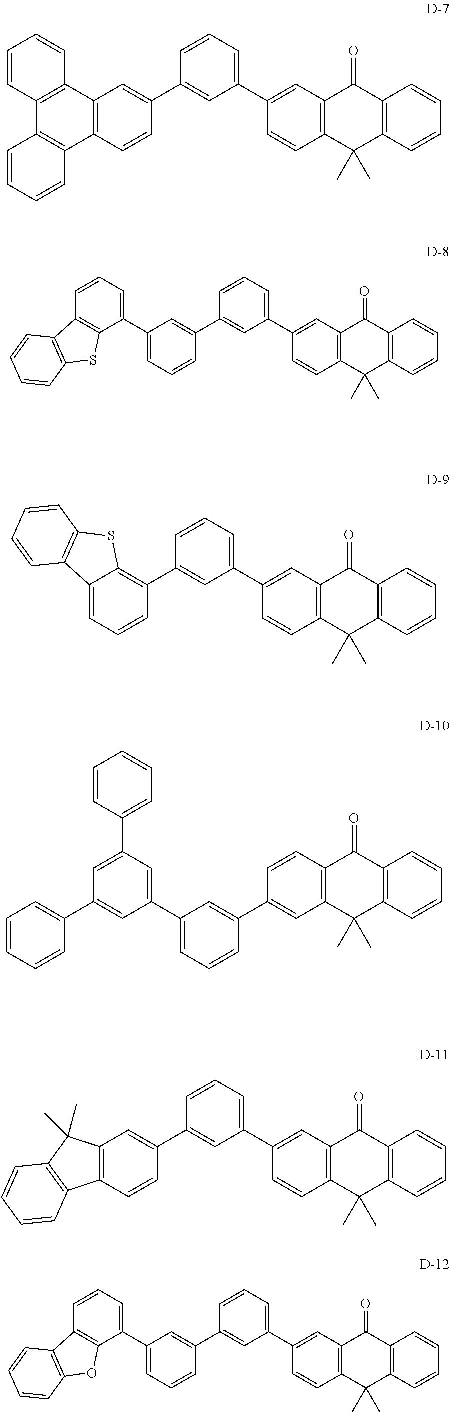 [SMILES: CC1(C)c2ccccc2C(=O)c2cc(-c3cccc(-c4ccc5c6ccccc6c6ccccc6c5c4)c3)ccc21 ; CC1(C)c2ccccc2C(=O)c2cc(-c3cccc(-c4cccc(-c5cccc6c5sc5ccccc56)c4)c3)ccc21 ; CC1(C)c2ccccc2C(=O)c2cc(-c3cccc(-c4cccc5c4sc4ccccc45)c3)ccc21 ; CC1(C)c2ccccc2C(=O)c2ccc(-c3cccc(-c4cc(-c5ccccc5)cc(-c5ccccc5)c4)c3)cc21 ; CC1(C)c2ccccc2C(=O)c2cc(-c3cccc(-c4ccc5c(c4)C(C)(C)c4ccccc4-5)c3)ccc21 ; CC1(C)c2ccccc2C(=O)c2cc(-c3cccc(-c4cccc(-c5cccc6c5oc5ccccc56)c4)c3)ccc21]

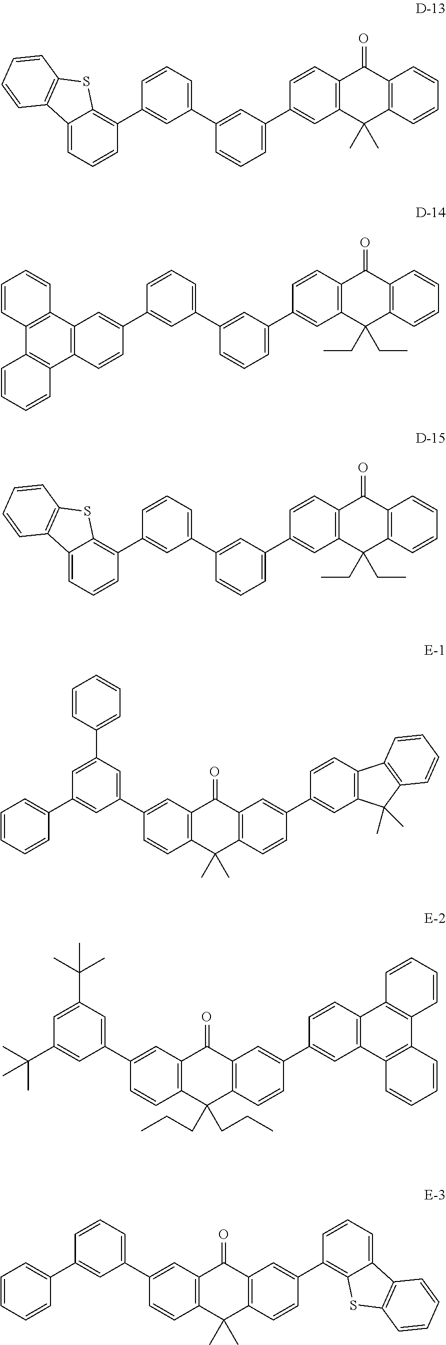 [SMILES: CC1(C)c2ccccc2C(=O)c2ccc(-c3cccc(-c4cccc(-c5cccc6c5sc5ccccc56)c4)c3)cc21 ; CCC1(CC)c2ccccc2C(=O)c2ccc(-c3cccc(-c4cccc(-c5ccc6c7ccccc7c7ccccc7c6c5)c4)c3)cc21 ; CCC1(CC)c2ccccc2C(=O)c2ccc(-c3cccc(-c4cccc(-c5cccc6c5sc5ccccc56)c4)c3)cc21 ; CC1(C)c2ccc(-c3cc(-c4ccccc4)cc(-c4ccccc4)c3)cc2C(=O)c2cc(-c3ccc4c(c3)C(C)(C)c3ccccc3-4)ccc21 ; CCCC1(CCC)c2ccc(-c3cc(C(C)(C)C)cc(C(C)(C)C)c3)cc2C(=O)c2cc(-c3ccc4c5ccccc5c5ccccc5c4c3)ccc21 ; CC1(C)c2ccc(-c3cccc(-c4ccccc4)c3)cc2C(=O)c2cc(-c3cccc4c3sc3ccccc34)ccc21]

Of the example compounds, those of Group A are compounds represented by general formula [1] having two identical substituents, with Ak₁ and Ak₂ each representing a methyl group, i.e., the shortest alkyl chain, and R₁ to R₈ each representing hydrogen or a hydrocarbon. When two identical substituents are introduced into the anthrone skeleton, which is the core skeleton, the skeleton has an axis of symmetry and thereby becomes stable. The compounds of Group A have very high chemical stability and electron transport property. Using any of these compounds as an electron transport material, a host material of an emission layer, or an assisting material of an emission layer will extend the lifetime of the organic light-emitting device.

Of the example compounds, those of Group B are compounds represented by general formula [1] with Ak₁ and Ak₂ each representing a substituent with an alkyl chain length longer than a methyl group and R₁ to R₈ each representing hydrogen or a hydrocarbon. The substitution positions for Ak₁ and Ak₂ are perpendicular to the plane of the anthrone skeleton. Accordingly, when the chain lengths of the alkyl groups at these positions are increased, the solubility in an organic solvent is improved. Thus, these compounds are suitable for not only vapor deposition but also coating processes.

Of the example compounds, those of Group C are compounds represented by general formula [1] with Ak₁ and Ak₂ each representing an alkyl group and at least one of R₁ to R₈ representing a substituent containing dibenzothiophene or dibenzofuran. These compounds having hetero atoms inside the cyclic groups exhibit stability close to that of the compounds having aromatic hydrocarbons. Accordingly, when a compound of Group C is used as an electron transport material, a host material of an emission layer, or an assisting material of an emission layer, the organic light-emitting device will have a longer lifetime.

Of the example compounds, those of Group D are compounds represented by general formula [1] with Ak₁ and Ak₂ each being an alkyl group and one of R₁ to R₈ representing a substituent. Since the compound is asymmetric, HOMO-LUMO may exhibit charge transfer (CT) property. This can be used to adjust the HOMO-LUMO to a level suitable for the light-emitting material. Thus, an organic light-emitting device that uses such a compound as an electron transfer material, a host material of an emission layer, or an assisting material of an emission layer will have a longer lifetime.

Of the example compounds, those of Group E are compounds based on a combination of the concepts underlying the compounds of Groups A to D. The solubility and mobility can be controlled by decreasing the symmetry and changing the alkyl chain length of Ak₁ and Ak₂.

### Method for Synthesizing the 10,10-Dialkylanthrone Compound

A method for synthesizing a 10,10-dialkylanthrone compound represented by formula [1] according to an embodiment will now be described.

A raw material, 10,10-dialkylanthrone can be synthesized through a scheme [2] below. During the synthesis, the CH₃ group of CH₃MgBr may be changed to a different alkyl group to change Ak₁ and Ak₂.

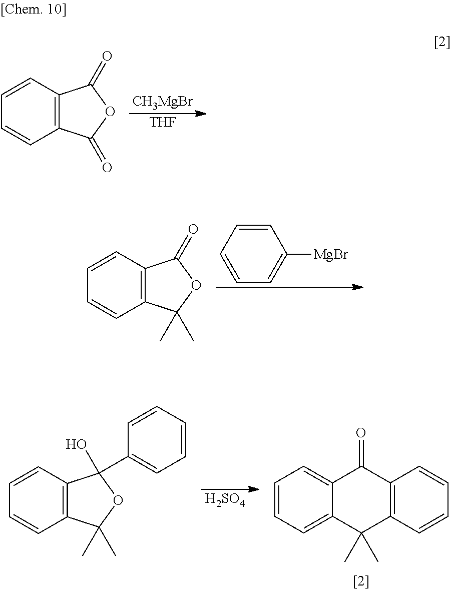

The 10,10-dialkylanthrone compound can be synthesized through a scheme [3] below that involves a coupling reaction between a halide (X) of 10,10-dialkylanthrone and a substituent (Ar), a boronic acid or a boronic acid ester compound catalyzed by a palladium catalyst.

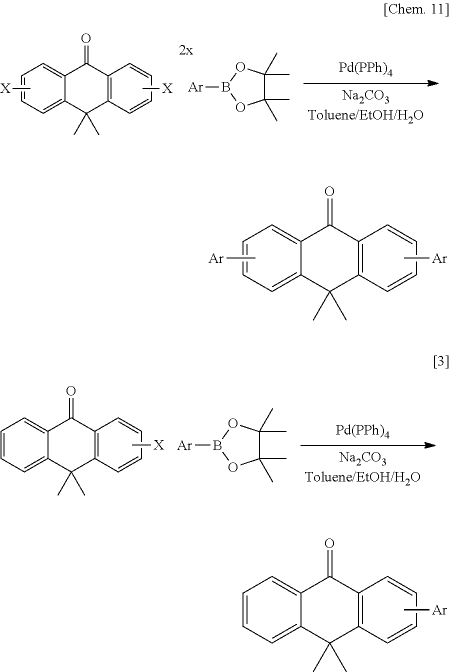

In the scheme [3], Ar is independently selected from a phenyl group, a naphthyl group, a phenanthrene group, a fluorenyl group, a triphenylene group, a dibenzofuran group, and a dibenzothiophene group.

In the reactions described above, the CH₃ group and Ar may be adequately selected to synthesize a desired 10,10-dialkylanthrone compound of the embodiment.

When the compound of the embodiment is used in an organic light-emitting device, the purification method conducted immediately before the fabrication process may be sublimation purification. This is because sublimation purification has an extensive purification effect in increasing the purity of an organic compound. According to sublimation purification, a high temperature is generally required to purify an organic compound having a high molecular weight and this high temperature is likely to cause thermal decomposition. Thus, the organic compound used in an organic light-emitting device may have a molecular weight of 1000 or less so that sublimation purification can be conducted without excessive heating.

### Regarding Organic Light-Emitting Device

Next, an organic light-emitting device according to an embodiment of the present invention is described.

An organic light-emitting device according to an embodiment of the present invention includes a pair of electrodes facing each other, i.e., an anode and a cathode, and an organic compound layer disposed between the anode and the cathode. In the organic compound layer, a layer containing a light-emitting material is the emission layer. The organic light-emitting device of the embodiment contains the 10,10-dialkylanthrone compound represented by general formula [1] in the organic compound layer.

The organic light-emitting device may have a structure in which an anode, an emission layer, and a cathode are sequentially stacked on a substrate. Examples of other possible structures include an anode/hole transport layer/electron transport layer/cathode structure, an anode/hole transport layer/emission layer/electron transport layer/cathode structure, an anode/hole injection layer/hole transport layer/emission layer/electron transport layer/cathode structure, and an anode/hole transport layer/emission layer/hole-exciton blocking layer/electron transport layer/cathode structure. However, these five examples of the multilayer organic light-emitting devices are merely basic device configurations and the structure of the organic light-emitting device containing the compound of the embodiment is not limited to these. Various other layer configurations may be employed, e.g., an insulating layer may be provided at the interface between an electrode and an organic compound layer, an adhesive layer or an interference layer may be provided, and the electron transport layer or the hole transport layer may be constituted by two layers having different ionization potentials.

The device may be of a top emission type that emits light from the substrate-side electrode or of a bottom emission type that emits light from the side opposite the substrate. The device may be of a type that emits light from both sides.

The 10,10-dialkylanthrone compound may be used in an organic compound layer of an organic light-emitting device having any of the aforementioned layer configurations but preferably used in an electron transport layer, a hole/exciton blocking layer, or an emission layer. More preferably, the compound is used as an electron transport material of an electron transport layer or a hole/exciton blocking layer or as a host material 2 of an emission layer.

When the 10,10-dialkylanthrone compound is used as an electron transport material, a host material 2, or a host material of a phosphorescent layer, the phosphorescent material used as the guest material is a metal complex such as an iridium complex, a platinum complex, a rhenium complex, a copper complex, a europium complex, or a ruthenium complex. Among these, iridium complex having a high phosphorescent property is preferred. The emission layer may contain two or more phosphorescent materials to assist the transmission of excitons and carriers.

Examples of the iridium complex used as the phosphorescent material and examples of the host material are provided below. Note that the present invention is not limited to these examples.

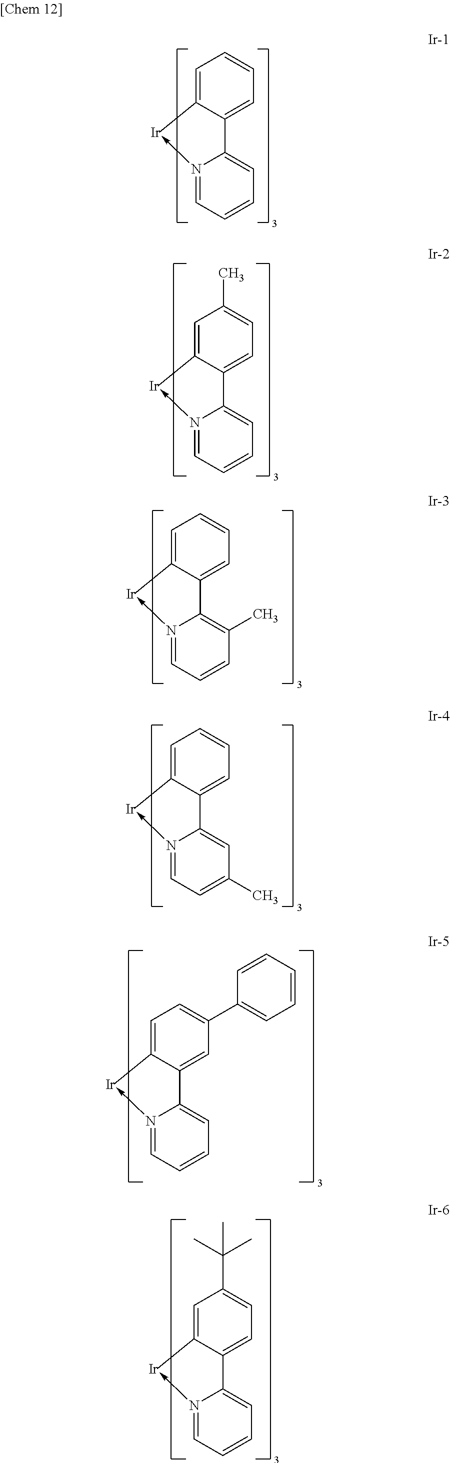

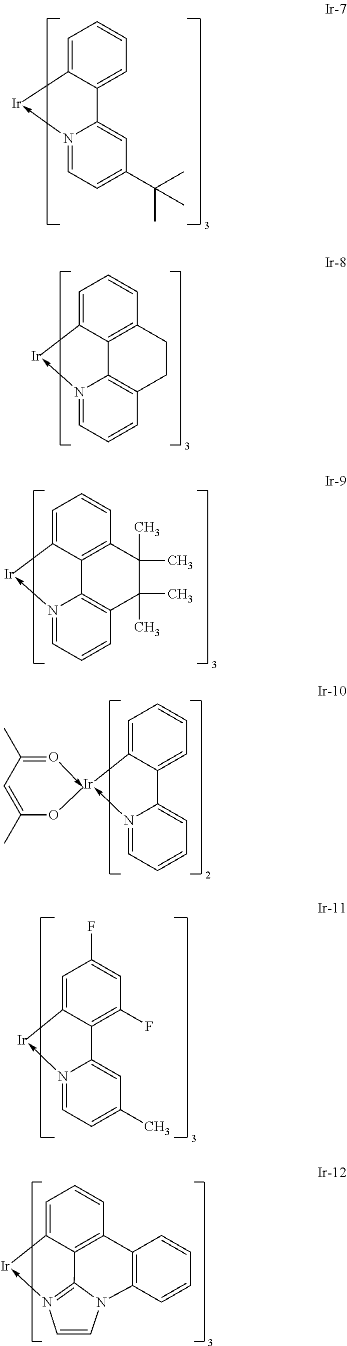

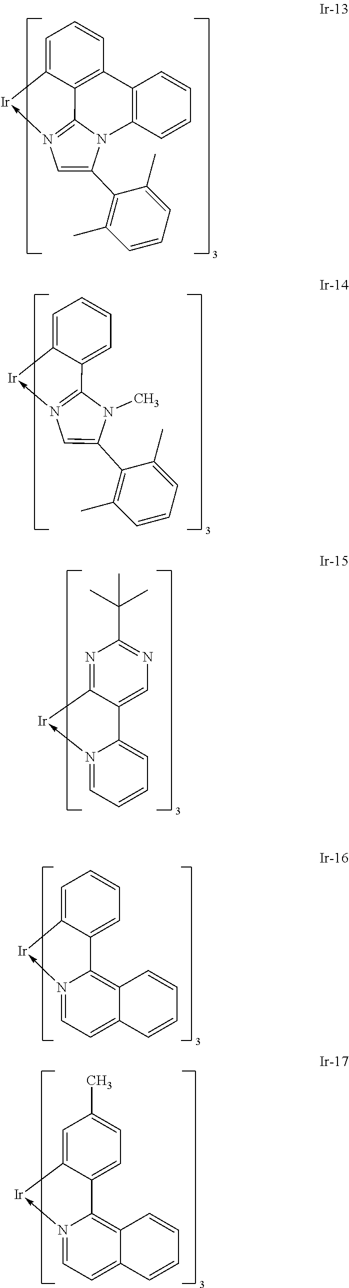

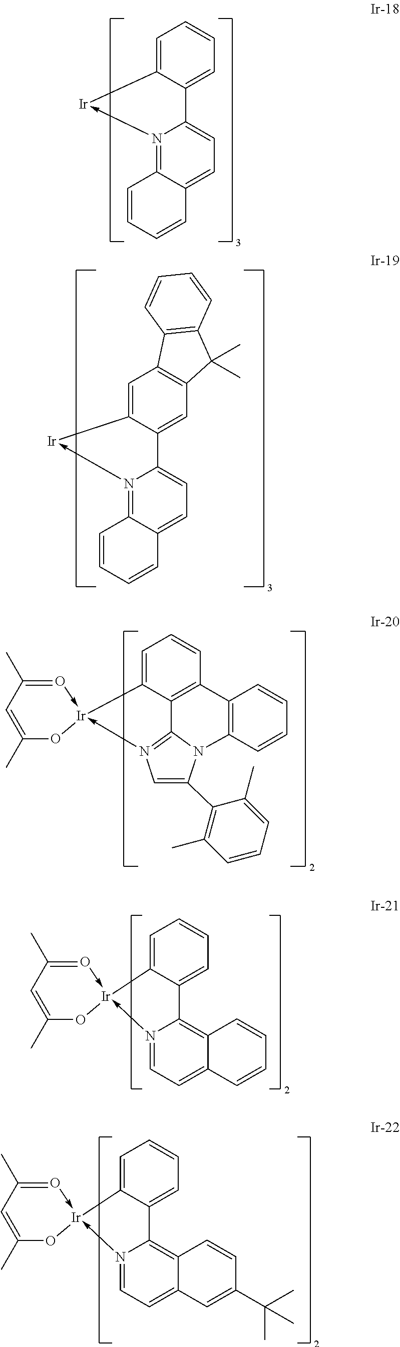

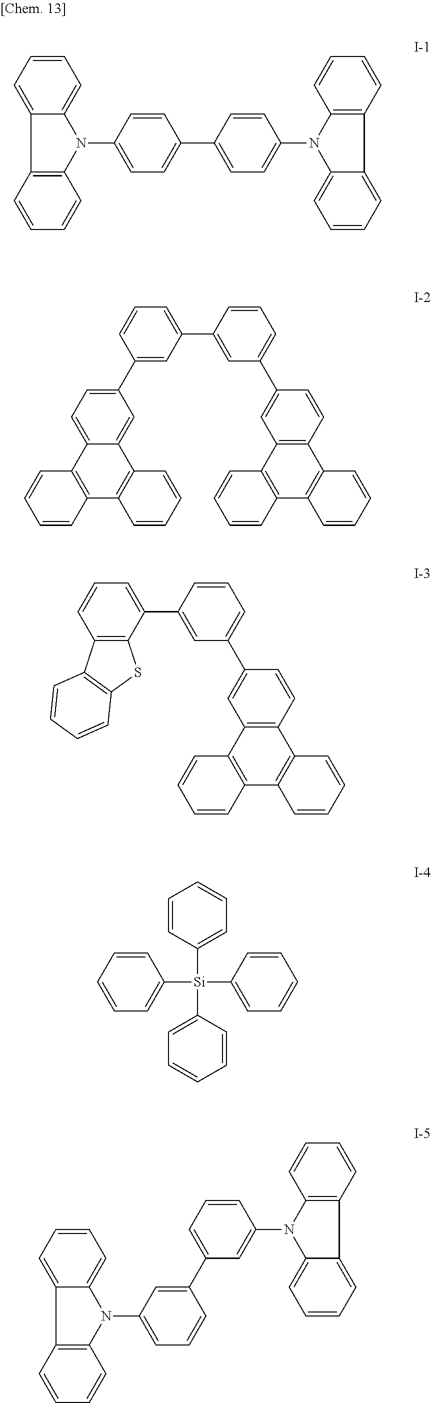

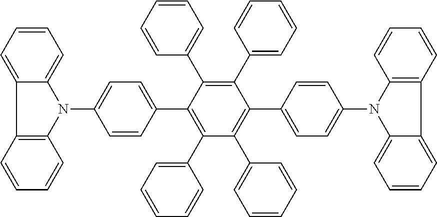 [SMILES: c1ccc(-c2c(-c3ccccc3)c(-c3ccc(-n4c5ccccc5c5ccccc54)cc3)c(-c3ccccc3)c(-c3ccccc3)c2-c2ccc(-n3c4ccccc4c4ccccc43)cc2)cc1]

If needed, a low-molecular-weight or high-molecular weight compound other than the compound of the embodiment may be used. In particular, a hole injection compound, a transport compound, a host material, a light-emitting compound, an electron injection compound, an electron transport material, or the like may be used in combination. Examples of these compounds are as follows.

The hole injection/transport material can be a material having a high hole mobility so that holes can be easily injected from the anode and the injected holes can be easily transported to the emission layer. Examples of the low- and high-molecular-weight materials having hole injection/transport property include triarylamine derivatives, phenylenediamine derivatives, stilbene derivatives, phthalocyanine derivatives, porphyrin derivatives, poly(vinyl carbazole), poly(thiophene), and other conductive polymers.

Examples of the light-emitting material mainly contributing to the light-emitting function include the phosphorescent guest materials described above, derivative thereof, fused compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, organic beryllium complexes, and polymer derivatives such as poly(phenylenevinylene) derivatives, poly(fluorene) derivatives, and poly(phenylene) derivatives.

The electron injection/transport material may be selected from materials to which electrons can be easily injected from the cathode and which can transport the injected electrons to the emission layer. The selection may be made by considering the balance with the hole mobility of the hole injection/transport material. Examples of the electron injection/transport material include oxadiazole derivatives, oxazole derivatives, pyrazine derivatives, triazole derivatives, triazine derivatives, quinoline derivatives, quinoxaline derivatives, phenanthroline derivatives, and organic aluminum complexes.

The anode material may have a large work function. Examples of the anode material include single metals such as gold, platinum, silver, copper, nickel, palladium, cobalt, selenium, vanadium, and tungsten or alloys thereof, and metal oxides such as tin oxide, zinc oxide, indium oxide, indium tin oxide (ITO), and indium zinc oxide. Conductive polymers such as polyaniline, polypyrrole, and polythiophene may also be used. These anode materials may be used alone or in combination. The anode may be constituted by one layer or two or more layers.

The cathode material may have a small work function. Examples of the cathode material include alkali metals such as lithium, alkaline earth metals such as calcium, and single metals such as aluminum, titanium, manganese, silver, lead, and chromium. The single metals may be combined and used as alloys. For example, magnesium-silver, aluminum-lithium, and aluminum-magnesium alloys and the like can be used. Metal oxides such as indium tin oxide (ITO) can also be used. These cathode materials may be used alone or in combination. The cathode may be constituted by one layer or two or more layers.

A layer containing the organic compound of the embodiment and a layer composed of other organic compound of the organic light-emitting device of the embodiment are prepared by the methods below. Typically, thin films are formed by vacuum vapor deposition, ionization deposition, sputtering, plasma, and coating using an adequate solvent (spin-coating, dipping, casting, a Langmuir Blodgett method, and an ink jet method). When layers are formed by vacuum vapor deposition or a solution coating method, crystallization is suppressed and stability over time can be improved. When a coating method is employed, an adequate binder resin may be additionally used to form a film.

Examples of the binder resin include, but are not limited to, polyvinylcarbazole resins, polycarbonate resins, polyester resins, ABS resins, acrylic resins, polyimide resins, phenolic resins, epoxy resins, silicone resins, and urea resins. These binder resins may be used alone as a homopolymer or in combination of two or more as a copolymer. If needed, known additives such as a plasticizer, an antioxidant, and an ultraviolet absorber may be used in combination.

### Usage of Organic Light-Emitting Device

The organic light-emitting device of the embodiment may be used in a display apparatus or a lighting apparatus. The organic light-emitting device can also be used as exposure light sources of image-forming apparatuses and backlights of liquid crystal display apparatuses.

A display apparatus includes a display unit that includes the organic light-emitting device of this embodiment. The display unit has pixels and each pixel includes the organic light-emitting device of this embodiment. The display apparatus may be used as an image display apparatus of a personal computer, etc.

The display apparatus may be used in a display unit of an imaging apparatus such as digital cameras and digital video cameras. An imaging apparatus includes the display unit and an imaging unit having an imaging optical system for capturing images.

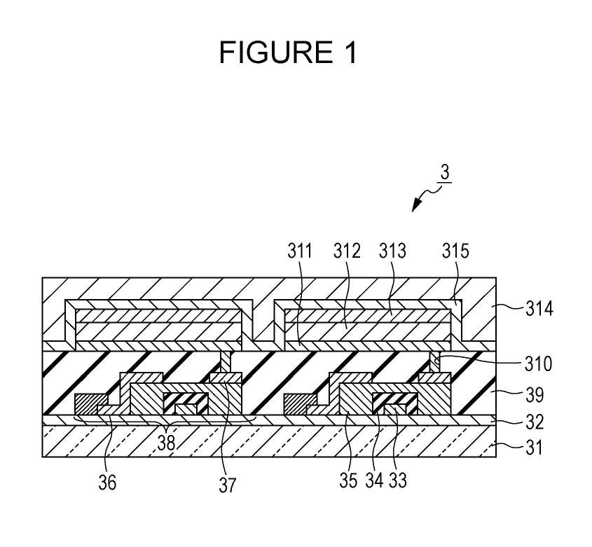

FIG. 1 is a schematic cross-sectional view of an image display apparatus having an organic light-emitting device in a pixel unit. In the drawing, two organic light-emitting devices and two thin film transistors (TFTs) are illustrated. One organic light-emitting device is connected to one TFT.

Referring to FIG. 1, in an image display apparatus 3, a moisture proof film 32 is disposed on a substrate 31 composed of glass or the like to protect components (TFT or organic layer) formed thereon. The moisture proof film 32 is composed of silicon oxide or a composite of silicon oxide and silicon nitride. A gate electrode 33 is provided on the moisture proof film 32. The gate electrode 33 is formed by depositing a metal such as Cr by sputtering.

A gate insulating film 34 covers the gate electrode 33. The gate insulating film 34 is obtained by forming a layer of silicon oxide or the like by a plasma chemical vapor deposition (CVD) method or a catalytic chemical vapor deposition (cat-CVD) method and patterning the film. A semiconductor layer 35 is formed over the gate insulating film 34 in each region that forms a TFT by patterning. The semiconductor layer 35 is obtained by forming a silicon film by a plasma CVD method or the like (optionally annealing at a temperature 290° C. or higher, for example) and patterning the resulting film according to the circuit layout.

A drain electrode 36 and a source electrode 37 are formed on each semiconductor layer 35. In sum, a TFT 38 includes a gate electrode 33, a gate insulating layer 34, a semiconductor layer 35, a drain electrode 36, and a source electrode 37. An insulating film 39 is formed over the TFT 38. A contact hole (through hole) 310 is formed in the insulating film 39 to connect between a metal anode 311 of the organic light-emitting device and the source electrode 37.

A single-layer or a multilayer organic layer 312 that includes an emission layer and a cathode 313 are stacked on the anode 311 in that order to constitute an organic light-emitting device that functions as a pixel.

First and second protective layers 314 and 315 may be provided to prevent deterioration of the organic light-emitting device.

The switching element is not particularly limited and a metal-insulator-metal (MIM) element may be used instead of the TFT described above.

### EXAMPLES

### Example 1

### Synthesis of Example Compound A-2

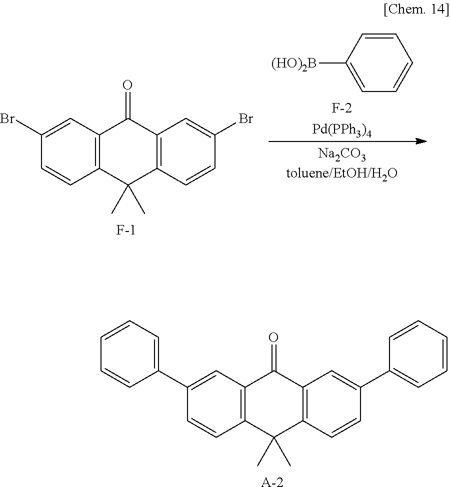

The following reagents and solvents were placed in a 200 mL round-bottomed flask.

F-1: 1.9 g (5 mmol)
F-2 (phenylboronic acid): 1.5 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 300° C. As a result, 1.4 g (yield: 75%) of high-purity Example Compound A-2 was obtained.

The compound obtained was identified by mass spectroscopy.

Matrix-assisted laser desorption ionization-time-of-flight mass spectroscopy (MALDI-TOF-MS)
Observed value: m/z=374.15
Calculated value: C₂₈H₂₂O=374.17

The T₁ energy of Example Compound A-2 was measured as by the following process.

A phosphorescence spectrum of a diluted toluene solution of Example Compound A-2 was measured in an Ar atmosphere at 77K and an excitation wavelength of 350 nm. The T₁ energy was calculated from the peak wavelength of the first emission peak of the obtained phosphorescence spectrum. The T₁ energy was 436 nm on a wavelength basis.

The energy gap of Example Compound A-2 was measured by the following process. Example Compound A-2 was vapor-deposited by heating on a glass substrate to obtain a deposited thin film 20 nm in thickness. An absorption spectrum of the deposited thin film was taken with a ultraviolet-visible spectrophotometer (V-560 produced by JASCO Corporation). The energy gap of Example Compound A-2 determined from the absorption edge of the absorption spectrum was 3.7 eV.

### Example 2

### Synthesis of Example Compound A-4

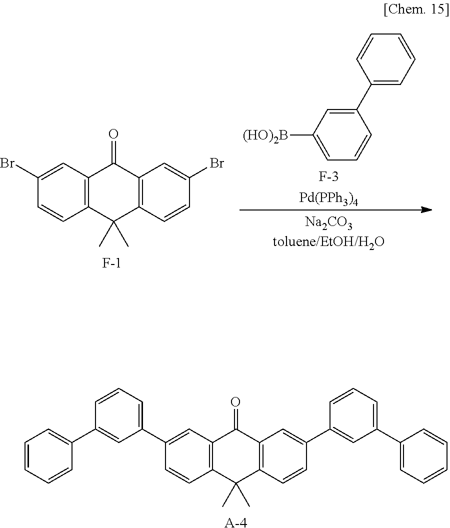

The following reagents and solvents were placed in a 200 mL round-bottomed flask.

F-1: 1.9 g (5 mmol)
F-3 (3-biphenylboronic acid): 2.4 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 310° C. As a result, 1.7 g (yield: 66%) of high-purity Example Compound A-4 was obtained.

### [MALDI-TOF-MS]

Observed value: m/z=526.27
Calculated value: 526.23

The T₁ energy of Example Compound A-4 was measured as in Example 1. The T₁ energy was 441 nm on a wavelength basis.

The energy gap of Example Compound A-4 was determined as in Example 1. The energy gap of Example Compound A-4 was 3.6 eV.

### Example 3

### Synthesis of Example Compound A-6

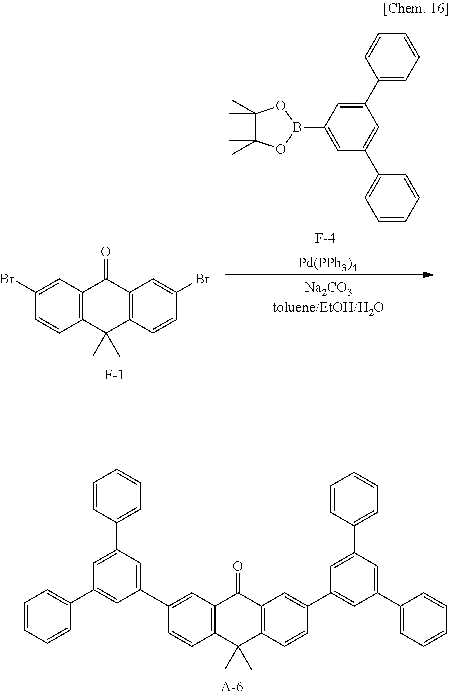

The following reagents and solvents were placed in a 200 mL round-bottomed flask.

F-1: 1.9 g (5 mmol)
F-4: 4.3 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in chlorobenzene under heating, subjected to hot filtration, and recrystallized twice with a chlorobenzene solvent. The obtained crystals were vacuum dried at 100° C. and purified by sublimation at 10⁻⁴ Pa and 340° C. As a result, 2.4 g (yield: 70%) of high-purity Example Compound A-6 was obtained.

### [MALDI-TOF-MS]

Observed value: m/z=678.25
Calculated value: 678.29

The T₁ energy of Example Compound A-6 was measured as in Example 1. The T₁ energy was 443 nm on a wavelength basis.

The energy gap of Example Compound A-6 was determined as in Example 1. The energy gap of Example Compound A-6 was 3.6 eV.

### Example 4

### Synthesis of Example Compound A-8

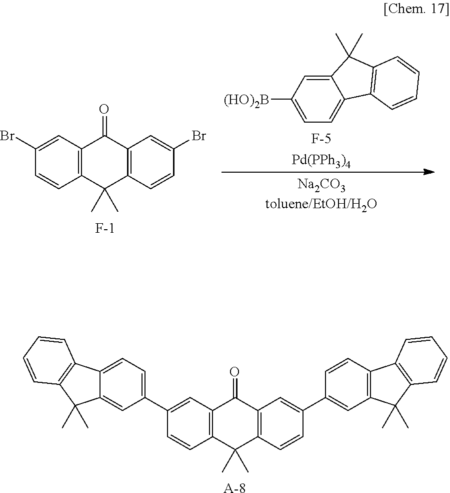

The following reagents and solvents were placed in a 200 mL round-bottomed flask.

F-1: 1.9 g (5 mmol)
F-5: 2.9 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 340° C. As a result, 1.9 g (yield: 62%) of high-purity Example Compound A-8 was obtained.

### [MALDI-TOF-MS]

Observed value: m/z=606.25
Calculated value: 606.29

The T₁ energy of Example Compound A-8 was measured as in Example 1. The T₁ energy was 482 nm on a wavelength basis. The energy gap of Example Compound A-8 was determined as in Example 1. The energy gap of Example Compound A-8 was 3.3 eV.

### Example 5

### Synthesis of Example Compound A-9

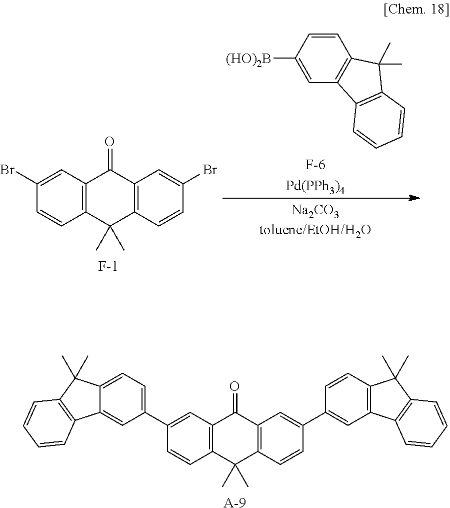

The following reagents and solvents were placed in a 200 mL round-bottomed flask.

F-1: 1.9 g (5 mmol)
F-6: 2.9 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 330° C. As a result, 2.1 g (yield: 70%) of high-purity Example Compound A-9 was obtained.

### [MALDI-TOF-MS]

Observed value: m/z=606.27
Calculated value: 606.29

The T₁ energy of Example Compound A-9 was measured as in Example 1. The T₁ energy was 465 nm on a wavelength basis.

### Example 6

### Synthesis of Example Compound A-13

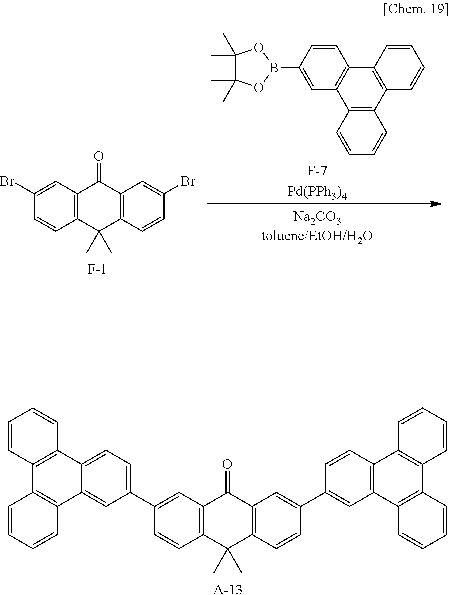

The following reagents and solvents were placed in a 200 mL round-bottomed flask.

F-1: 1.9 g (5 mmol)
F-7: 4.3 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in chlorobenzene under heating, subjected to hot filtration, and recrystallized twice with a chlorobenzene solvent. The obtained crystals were vacuum dried at 100° C. As a result, 1.4 g (yield: 42%) of high-purity Example Compound A-13 was obtained.

### [MALDI-TOF-MS]

Observed value: m/z=674.22
Calculated value: 674.26

The T₁ energy of Example Compound A-13 was measured as in Example 1. The T₁ energy was 472 nm on a wavelength basis.

The energy gap of Example Compound A-13 was determined as in Example 1. The energy gap of Example Compound A-13 was 3.5 eV.

### Example 7

### Synthesis of Example Compound A-16

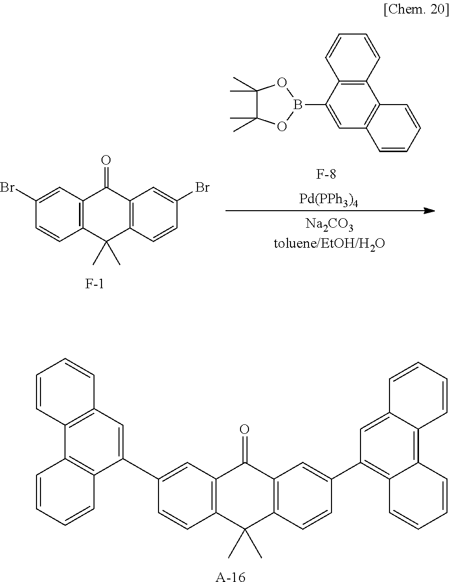

The following reagents and solvents were placed in a 200 mL round-bottomed flask.

F-1: 1.9 g (5 mmol)
F-8: 3.6 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 320° C. As a result, 2.1 g (yield: 72%) of high-purity Example Compound A-16 was obtained.

### [MALDI-TOF-MS]

Observed value: m/z=574.42
Calculated value: 574.23

The T₁ energy of Example Compound A-16 was measured as in Example 1. The T₁ energy was 498 nm on a wavelength basis.

The energy gap of Example Compound A-16 was determined as in Example 1. The energy gap of Example Compound A-16 was 3.6 eV.

### Example 8

### Synthesis of Example Compound A-21

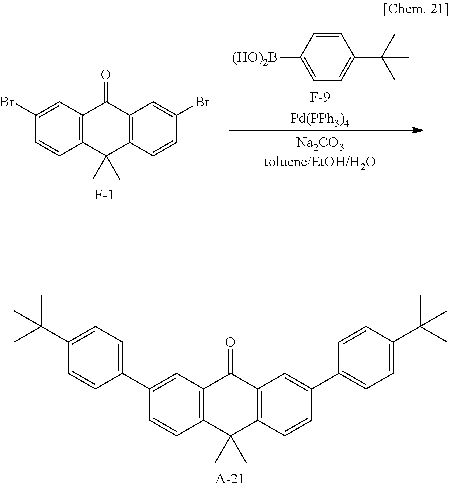

The following reagents and solvents were placed in a 200 mL round-bottomed flask.

F-1: 1.9 g (5 mmol)
F-9: 2.1 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 310° C. As a result, 1.7 g (yield: 68%) of high-purity Example Compound A-21 was obtained.

### [MALDI-TOF-MS]

Observed value: m/z=486.15
Calculated value: 486.29

The T₁ energy of Example Compound A-21 was measured as in Example 1. The T₁ energy was 440 nm on a wavelength basis.

The energy gap of Example Compound A-21 was determined as in Example 1. The energy gap of Example Compound A-21 was 3.6 eV.

### Example 9

### Synthesis of Example Compound A-29

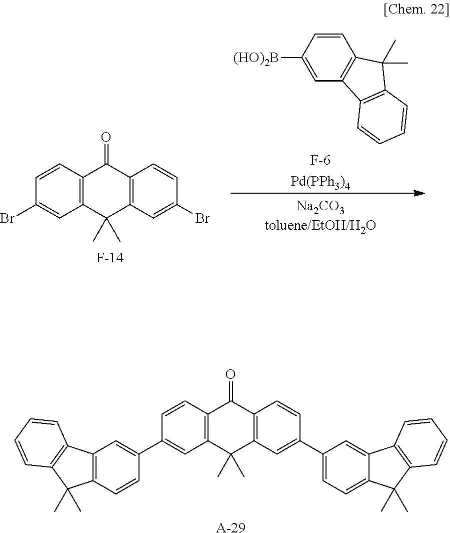

The following reagents and solvents were placed in a 200 mL round-bottomed flask.

F-14: 1.9 g (5 mmol)
F-6: 2.9 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 340° C. As a result, 2.1 g (yield: 70%) of high-purity Example Compound A-29 was obtained.

### [MALDI-TOF-MS]

Observed value: m/z=606.21
Calculated value: 606.29

The T₁ energy of Example Compound A-29 was measured as in Example 1. The T₁ energy was 470 nm on a wavelength basis.

The energy gap of Example Compound A-29 was determined as in Example 1. The energy gap of Example Compound A-29 was 3.5 eV.

### Example 10

### Synthesis of Example Compound B-8

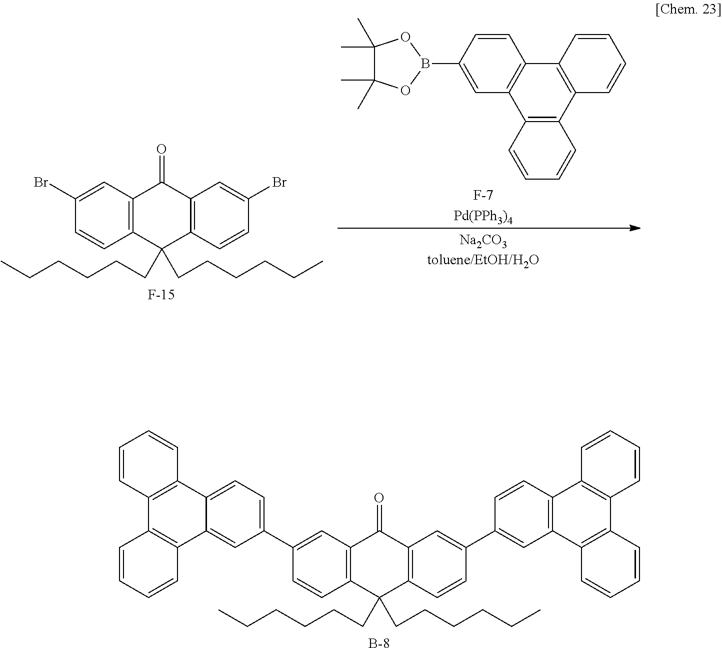

The following reagents and solvents were placed in a 200 mL round-bottomed flask.

F-15: 2.6 g (5 mmol)
F-7: 4.3 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water and ethanol to obtain a crude product. The crude product was dissolved in toluene under heating, subjected to hot filtration, column-purified with toluene/heptane, and recrystallized twice with toluene/ethanol. The obtained crystals were vacuum dried at 100° C. As a result, 2.4 g (yield: 60%) of high-purity Example Compound B-8 was obtained.

### [MALDI-TOF-MS]

Observed value: m/z=814.46
Calculated value: 814.42

The T₁ energy of Example Compound B-8 was measured as in Example 1. The T₁ energy was 473 nm on a wavelength basis.

The energy gap of Example Compound B-8 was determined as in Example 1. The energy gap of Example Compound B-8 was 3.5 eV.

### Example 11

### Synthesis of Example Compound C-1

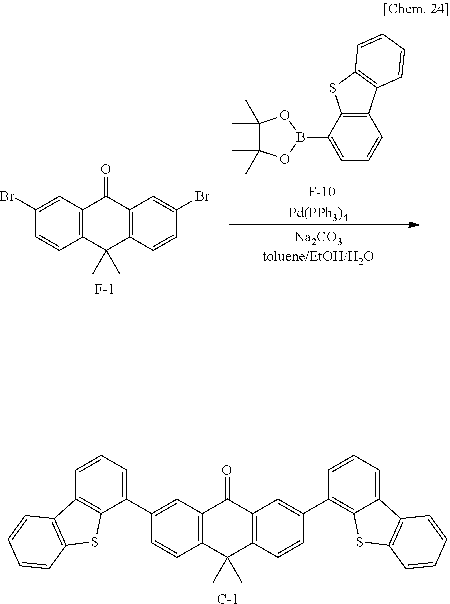

The following reagents and solvents were placed in a 200 mL round-bottomed flask.

F-1: 1.9 g (5 mmol)
F-10: 3.7 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 330° C. As a result, 2.1 g (yield: 72%) of high-purity Example Compound C-1 was obtained.

### [MALDI-TOF-MS]

Observed value: m/z=586.12
Calculated value: 586.14

The T₁ energy of Example Compound C-1 was measured as in Example 1. The T₁ energy was 445 nm on a wavelength basis. The energy gap of Example Compound C-1 was determined as in Example 1. The energy gap of Example Compound C-1 was 3.4 eV.

### Example 12

### Synthesis of Example Compound C-2

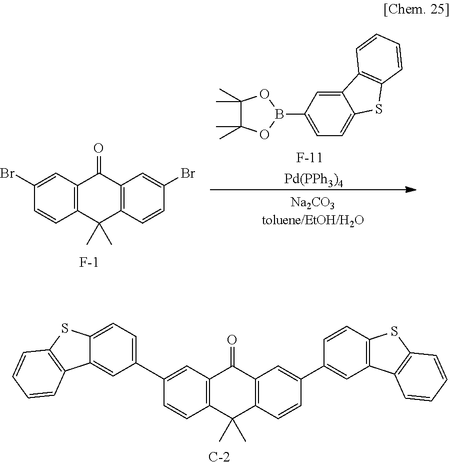

The following reagents and solvents were placed in a 200 mL round-bottomed flask.

F-1: 1.9 g (5 mmol)
F-11: 3.7 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 330° C. As a result, 1.9 g (yield: 65%) of high-purity Example Compound C-2 was obtained.

### [MALDI-TOF-MS]

Observed value: m/z=586.11
Calculated value: 586.14

The T₁ energy of Example Compound C-2 was measured as in Example 1. The T₁ energy was 450 nm on a wavelength basis.

The energy gap of Example Compound C-2 was determined as in Example 1. The energy gap of Example Compound C-2 was 3.3 eV.

### Example 13

### Synthesis of Example Compound C-3

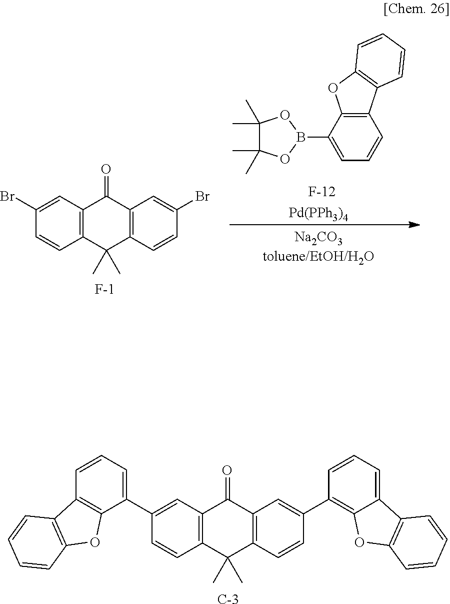

The following reagents and solvents were placed in a 200 mL round-bottomed flask.

F-1: 1.9 g (5 mmol)
F-12: 3.5 g (12 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 3 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene solvent. The obtained crystals were vacuum dried at 100° C. and purified by sublimation at 10⁻⁴ Pa and 320° C. As a result, 1.9 g (yield: 70%) of high-purity Example Compound C-3 was obtained.

### [MALDI-TOF-MS]

Observed value: m/z=554.12
Calculated value: C₄₆H₃₈O=554.19

The T₁ energy of Example Compound C-3 was measured as in Example 1. The T₁ energy was 443 nm on a wavelength basis.

The energy gap of Example Compound C-3 was determined as in Example 1. The energy gap of Example Compound C-3 was 3.5 eV.

### Example 14

### Synthesis of Example Compound D-1

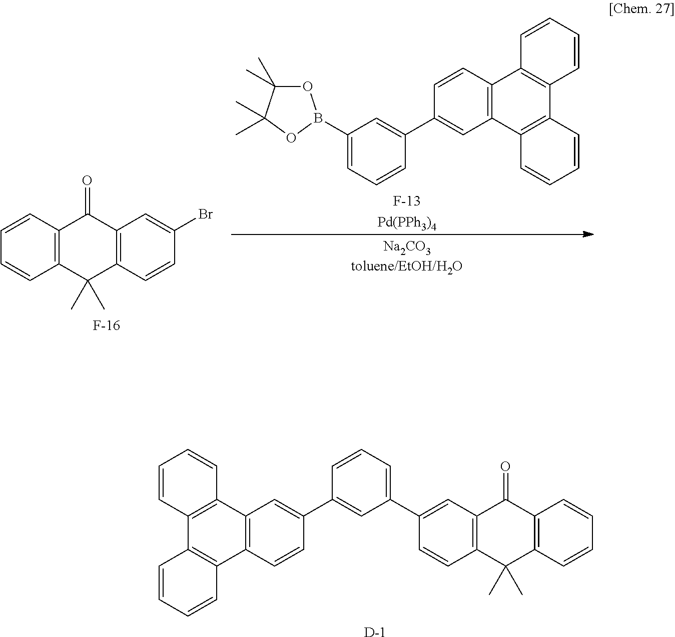

The following reagents and solvents were placed in a 200 mL round-bottomed flask.

F-16: 1.5 g (5 mmol)
F-13: 2.6 g (6 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 6 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene/heptane mixed solvent. The obtained crystals were vacuum dried at 100° C. and purified by sublimation at 10⁻⁴ Pa and 330° C. As a result, 2.1 g (yield: 72%) of high-purity Example Compound D-1 was obtained.

### [MALDI-TOF-MS]

Observed value: m/z=524.23
Calculated value: 524.21

The T₁ energy of Example Compound D-1 was measured as in Example 1. The T₁ energy was 480 nm on a wavelength basis.

The energy gap of Example Compound D-1 was determined as in Example 1. The energy gap of Example Compound D-1 was 3.4 eV.

### Example 15

### Synthesis of Example Compound D-8

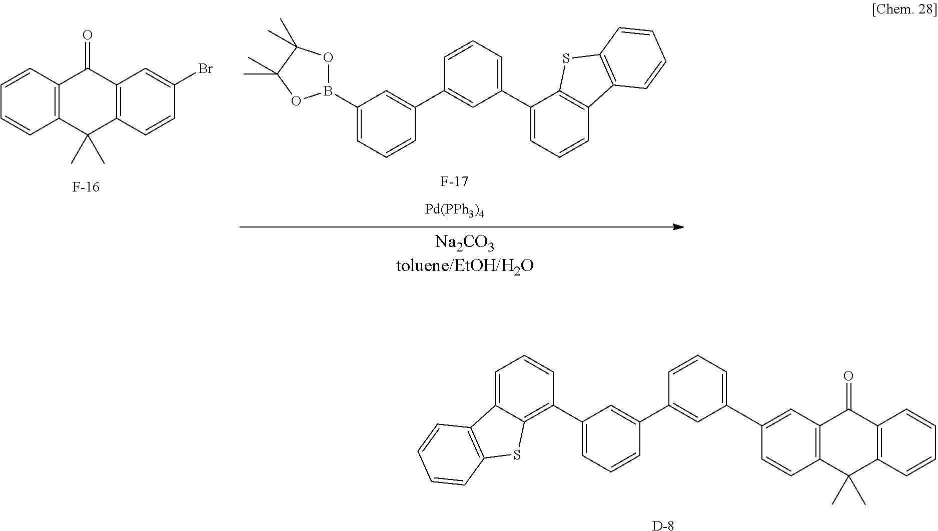

The following reagents and solvents were placed in a 200 mL round-bottomed flask.

F-16: 1.5 g (5 mmol)
F-17: 2.8 g (6 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 6 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene/methanol mixed solvent. The obtained crystals were vacuum dried at 100° C. and purified by sublimation at 10⁻⁴ Pa and 310° C. As a result, 1.6 g (yield: 58%) of high-purity Example Compound D-8 was obtained.

### [MALDI-TOF-MS]

Observed value: m/z=556.12
Calculated value: 556.19

The T₁ energy of Example Compound D-8 was measured as in Example 1. The T₁ energy was 445 nm on a wavelength basis.

The energy gap of Example Compound D-8 was determined as in Example 1. The energy gap of Example Compound D-8 was 3.4 eV.

### Example 16

### Synthesis of Example Compound D-3

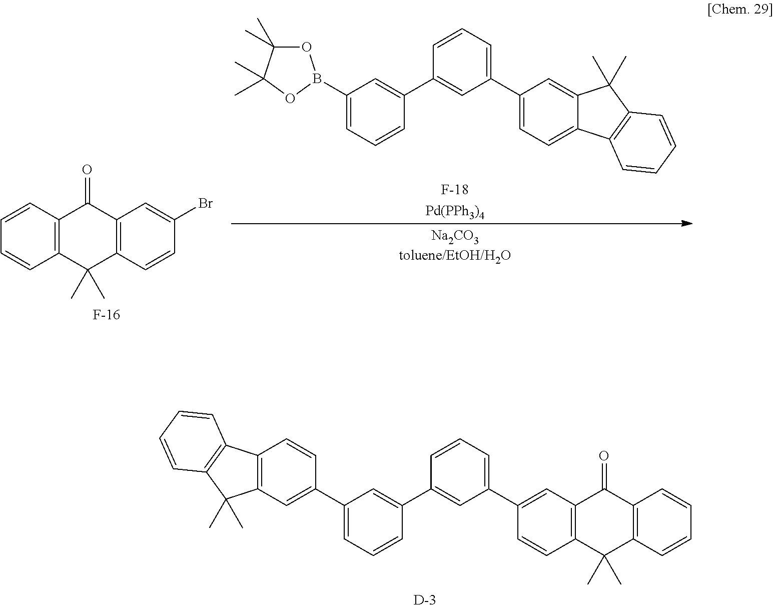

The following reagents and solvents were placed in a 200 mL round-bottomed flask.

F-16: 1.5 g (5 mmol)
F-18: 2.8 g (6 mmol)
Tetrakis(triphenylphosphine)palladium(0): 137 mg (0.12 mmol)

### Toluene: 50 mL

### Ethanol: 20 mL

30 wt % Aqueous sodium carbonate solution: 30 mL

The reaction solution was refluxed for 6 hours under heating and stirring in a nitrogen atmosphere. Upon completion of the reaction, water was added to the reaction solution, followed by stirring. The precipitated crystals were separated by filtration and washed with water, ethanol, and acetone to obtain a crude product. The crude product was dissolved in toluene under heating, subjected to hot filtration, and recrystallized twice with a toluene/ethanol mixed solvent. The obtained crystals were vacuum dried at 100° C. and purified by sublimation at 10⁻⁴ Pa and 320° C. As a result, 1.8 g (yield: 65%) of high-purity Example Compound D-3 was obtained.

### [MALDI-TOF-MS]

Observed value: m/z=566.01
Calculated value: 566.26

The T₁ energy of Example Compound D-3 was measured as in Example 1. The T₁ energy was 468 nm on a wavelength basis.

The energy gap of Example Compound D-3 was determined as in Example 1. The energy gap of Example Compound D-3 was 3.4 eV.

### Example 17

In this example, an organic light-emitting device having an anode/hole transport layer/emission layer/hole blocking layer/electron transport layer/cathode structure on a substrate was prepared as follows.

Indium tin oxide (ITO) was sputter-deposited on a glass substrate to form a film 120 nm in thickness functioning as an anode. This substrate was used as a transparent conductive support substrate (ITO substrate). Organic compound layers and electrode layers below were continuously formed on the ITO substrate by vacuum vapor deposition under resistive heating in a 10⁻⁵ Pa vacuum chamber. The process was conducted so that the area of the opposing electrodes was 3 mm².

Hole transport layer (40 nm) HTL-1
Emission layer (30 nm)

Host material 1: E ML-1

Host material 2: none

Guest material: Ir-1 (10 wt %)

Hole blocking (HB) layer (10 nm) A-2
Electron transport layer (30 nm) ETL-1
Metal electrode layer 1 (0.5 nm) LiF
Metal electrode layer 2 (100 nm) Al

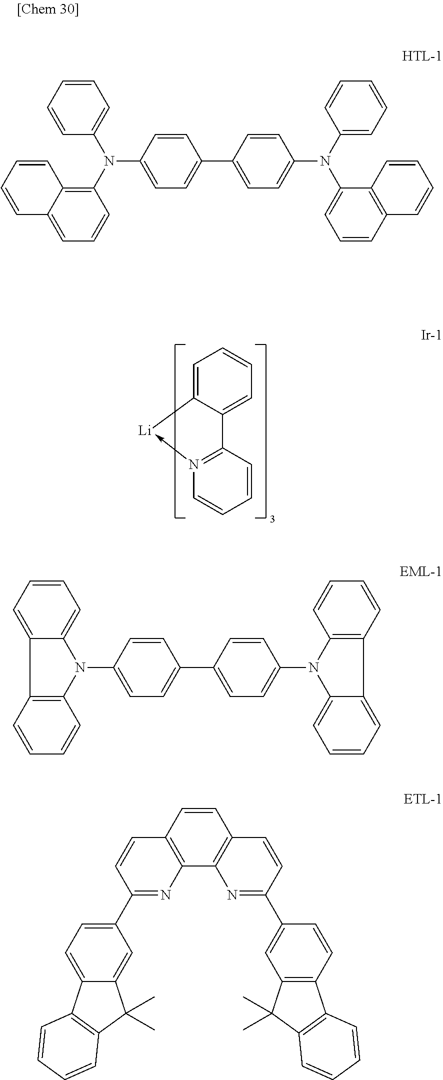

A protective glass plate was placed over the organic light-emitting device in dry air to prevent deterioration caused by adsorption of moisture and sealed with an acrylic resin adhesive. Thus, an organic light-emitting device was produced.

A voltage of 5.1V was applied to the ITO electrode functioning as a positive electrode and an aluminum electrode functioning as a negative electrode of the resulting organic light-emitting device. The emission efficiency was 50 cd/A and emission of green light with a luminance of 2000 cd/m² was observed. The CIE color coordinate of the device was (x, y)=(0.30, 0.63).

### Examples 18 to 29

Devices were produced as in Example 17 except that the HB material, the host material 1, the host material 2, and the guest material of the emission layer were changed. The devices were evaluated as in Example 17. The results are shown in Table 2.

TABLE 2

| | | | | | Emission | | |
|---|---|---|---|---|---|---|---|
| | HB | Host | Host | Guest | efficiency | Voltage | Emission |
| | material | material 1 | material 2 | material | (cd/A) | (V) | color |
| Ex. 18 | A2 | I-5 | None | Ir-13 | 10 | 6.5 | Blue |
| Ex. 19 | A4 | I-1 | A4 (15 wt %) | Ir-1 | 60 | 5.5 | Green |
| Ex. 20 | A4 | I-2 | None | Ir-1 | 56 | 5.2 | Green |
| Ex. 21 | A4 | I-2 | A4 (15 wt %) | Ir-1 | 62 | 5.2 | Green |
| Ex. 22 | A8 | I-1 | A8 (15 wt %) | Ir-1 | 61 | 5.5 | Green |
| Ex. 23 | A8 | I-3 | None | Ir-4 | 55 | 5.6 | Green |
| Ex. 24 | A9 | I-3 | None | Ir-1 | 58 | 5.5 | Green |
| Ex. 25 | A9 | I-5 | A9 (15 wt %) | Ir-3 | 63 | 5.0 | Green |
| Ex. 26 | A29 | I-1 | A2 (15 wt %) | Ir-1 | 63 | 5.1 | Green |
| Ex. 27 | C1 | I-4 | None | Ir-15 | 13 | 6.4 | Blue green |
| Ex. 28 | C1 | I-4 | C1 (10 wt %) | Ir-15 | 17 | 6.4 | Blue green |
| Ex. 29 | D3 | I-6 | D3 (15 wt %) | Ir-13 | 11 | 6.8 | Green |

Ex.: Example

The results show that when the 10,10-dialkylanthrone compound is used as an electron transport material or an emission layer material of an phosphorescent organic light-emitting device, good emission efficiency can be obtained.

### Examples 30 and 31 and Comparative Examples 1 and 2

Devices were produced as in Example 17 except that the HB material, the host material 1, the host material 2, and the guest material of the emission layer were changed. The devices were evaluated as in Example 17. The half luminance lifetime of each organic light-emitting device at a current value of 40 mA/cm² was measured to evaluate the stability of the device. The results are shown in Table 3.

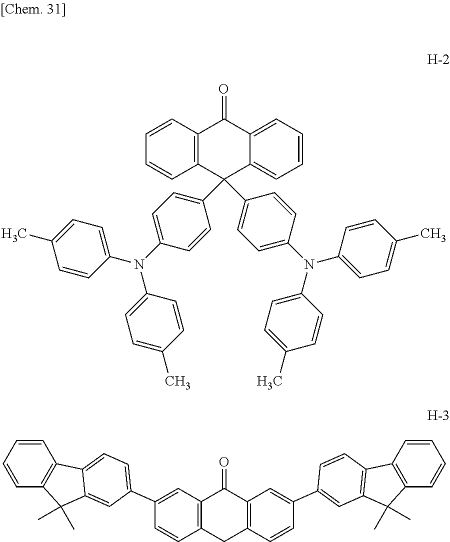

TABLE 3

| | | | | | Luminance |
|---|---|---|---|---|---|
| | HB | Host | Host | Guest | half lifetime |
| | material | material 1 | material 2 | material | (Hr) |
| Ex. 30 | A4 | I-3 | None | Ir-1 | 300 |
| Ex. 31 | A8 | I-3 | None | Ir-1 | 380 |
| C. E. 1 | H2 | I-3 | None | Ir-1 | 30 |
| C. E. 2 | H3 | I-3 | None | Ir-1 | 70 |

Ex.: Example
C.E.: Comparative Example

The 10,10-dialkylanthrone compound extends the half luminance lifetime of phosphorescent organic light-emitting device compared to the compounds in the cited literature. This is because the structure in an excited state becomes more stable due to the introduction of alkyl groups at the 10-position of the anthrone compound than when related compounds having hydrogen or phenyl groups are used. Accordingly, it has been found that when the 10,10-dialkylanthrone compound is used, the lifetime of the organic light-emitting device can be extended.

As has been discussed above with reference to the embodiments and examples, the present invention can provide a novel 10,10-dialkylanthrone compound that has a T₁ energy of 2.3 eV or more and a LUMO level of 2.7 eV or more. It also provides an organic light-emitting device that contains the 10,10-dialkylanthrone compound and exhibits high emission efficiency and low driving voltage.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-101298, filed Apr. 26, 2010, which is hereby incorporated by reference herein in its entirety.

1-2. (canceled)

3. An organic light-emitting device comprising:
a pair of electrodes; and
an organic compound layer interposed between the pair of electrodes,
wherein the organic compound layer contains a 10,10-dialkylanthrone compound represented by general formula [1] 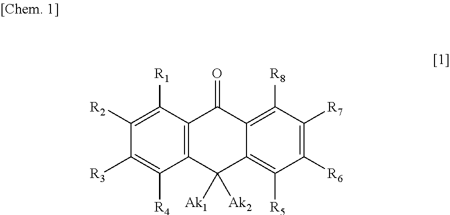
wherein R₁ to R₈ are each independently selected from a hydrogen atom, an alkyl group having 1 to 4 carbon atoms, a phenyl group, a biphenyl group, a naphthyl group, a phenanthrene group, a fluorenyl group, a triphenylene group, a dibenzofuran group, and a dibenzothiophene group;
the alkyl group having 1 to 4 carbon atoms, the phenyl group, the biphenyl group, the naphthyl group, the phenanthrene group, the fluorenyl group, the triphenylene group, the dibenzofuran group, and the dibenzothiophene group may have an alkyl group, an aromatic hydrocarbon group, or a heteroaromatic group as a substituent; and
Ak₁ and Ak₂ are each individually selected from alkyl rows having 1 to 6 carbon atoms.

4. The organic light-emitting device according to claim 3, wherein the organic compound layer is at least one of an electron transport layer and an emission layer.

5. The organic light-emitting device according to claim 4, wherein the organic compound layer is the emission layer, the emission layer contains a host material and a guest material, the host material contains a plurality of types of materials, and one of the plurality of types of materials is the 10,10-dialkylanthrone compound.

6. The organic light-emitting device according to claim 5, wherein the guest material is a phosphorescent material.

7. The organic light-emitting device according to claim 6, wherein the phosphorescent material is an iridium complex.

8. An image display apparatus comprising:
the organic light-emitting device according to claim 3; and
a switching element connected to the organic light-emitting device.

9. The organic light-emitting device according to claim 3, wherein all of R₁, R₄, R₅ and R₆ in general formula [1] are a hydrogen atom.
